(19) United States
(12) Patent Application Publication
(10) Pub. No.: US 2025/0017082 A1
(43) Pub. Date: Jan. 9, 2025

(54) LIGHT EMITTING DEVICE AND ELECTRONIC DEVICE

(71) Applicant: SONY SEMICONDUCTOR SOLUTIONS CORPORATION, KANAGAWA (JP)

(72) Inventors: TAKAYOSHI KATO, KANAGAWA (JP); DAISUKE HAMASHITA, KANAGAWA (JP); NAOYA KASAHARA, KANAGAWA (JP); TOSHIAKI SHIRAIWA, KANAGAWA (JP); MASAYA OGURA, KANAGAWA (JP)

(21) Appl. No.: 18/711,067

(22) PCT Filed: Nov. 14, 2022
(86) PCT No.: PCT/JP2022/042213

§ 371 Date: May 16, 2024

(30) Foreign Application Priority Data
Nov. 26, 2021 (JP) 2021-192246

(51) Int. Cl. H10K 59/80; H10K 59/131; H10K 59/35; H10K 59/38

(52) U.S. Cl. CPC H10K 59/873; H10K 59/131; H10K 59/353; H10K 59/38; H10K 59/879

(57) ABSTRACT

Provided is a light emitting device including a plurality of light emitting elements (300) that is arranged in a matrix on a semiconductor substrate (200), in which each of the light emitting elements provided to be covered with a first protective film includes a stack that includes a first electrode (302), a light emitting layer (304) provided on the first electrode, a second electrode (306) provided on the light emitting layer, and a second protective film (308) provided on the second electrode, and a side wall (310) that is formed of a material having a refractive index different from that of a material forming the first protective film and covering at least part of a side surface of the stack, in which the side wall extends from a position above an upper surface of the second electrode to a position below an upper surface of the light emitting layer, downward in a stacking direction.

### FIELD

The present disclosure relates to a light emitting device and an electronic device.

### BACKGROUND

As a display device in place of a liquid crystal display device, organic electroluminescence device (hereinafter, referred to as light emitting device) has been developed that uses an organic electroluminescence element (hereinafter, referred to as light emitting element).

An example of the light emitting device includes a top emission light emitting device that extracts white light from a light emitting layer of the light emitting element positioned on the lower side to the outside through a color filter positioned on the upper side. The top emission type enables efficient extraction of light, consumption of low power, and achievement of long life.

### CITATION LIST

### Patent Literature

Patent Literature 1: JP 2011-65773 A
Patent Literature 2: JP 2014-35799 A
Patent Literature 3: JP 2014-197525 A

### SUMMARY

### Technical Problem

For the light emitting device described above, further improvement in light extraction efficiency is strongly requested along with further miniaturization of the light emitting element. However, in the conventional art, there is a limit in improving the light extraction efficiency.

Therefore, the present disclosure proposes a light emitting device and an electronic device that are configured to provide further improved light extraction efficiency.

### Solution to Problem

According to the present disclosure, there is provided a light emitting device including a plurality of light emitting elements that is arranged in a matrix on a semiconductor substrate. In the light emitting device, each of the light emitting elements provided to be covered with a first protective film includes: a stack that includes a first electrode, a light emitting layer provided on the first electrode, a second electrode provided on the light emitting layer, and a second protective film provided on the second electrode; and a side wall that is formed of a material having a refractive index different from that of a material forming the first protective film and covering at least part of a side surface of the stack, and the side wall extends from a position above an upper surface of the second electrode to a position below an upper surface of the light emitting layer, downward in a stacking direction.

Furthermore, according to the present disclosure, there is provided an electronic device including one or a plurality of light emitting devices. In the electronic device, each of the light emitting devices includes a plurality of light emitting elements that is arranged in a matrix on a semiconductor substrate, each of the light emitting elements provided to be covered with a first protective film includes: a stack that includes a first electrode, a light emitting layer provided on the first electrode, a second electrode provided on the light emitting layer, and a second protective film provided on the second electrode; and a side wall that is formed of a material having a refractive index different from that of a material forming the first protective film and covering at least part of a side surface of the stack, and the side wall extends from a position above an upper surface of the second electrode to a position below an upper surface of the light emitting layer, downward in a stacking direction.

### BRIEF DESCRIPTION OF DRAWINGS

FIG. 1 is a cross-sectional view schematically illustrating an example of a planar structure of a light emitting device 10 according to an embodiment of the present disclosure.

FIG. 2 is an equivalent circuit diagram of an example of a drive circuit unit 40 of the light emitting device 10 according to an embodiment of the present disclosure.

FIG. 3 is an explanatory diagram illustrating a background of a first embodiment of the present disclosure.

FIG. 4 is an explanatory diagram illustrating an overview of a cross-sectional structure of a light emitting element 300 according to the first embodiment of the present disclosure.

FIG. 5 is an explanatory diagram illustrating an overview of a cross-sectional structure of the light emitting device 10 according to the first embodiment of the present disclosure.

FIG. 6 is an explanatory diagram (1) illustrating details of a structure of the light emitting element 300 according to the first embodiment of the present disclosure.

FIG. 7 is an explanatory diagram (2) illustrating details of a structure of the light emitting element 300 according to the first embodiment of the present disclosure.

FIG. 8 is an explanatory diagram illustrating the light emitting element 300 according to a modification of the first embodiment of the present disclosure.

FIG. 9 is an explanatory diagram illustrating an example of a planar arrangement of the light emitting elements 300 according to the first embodiment of the present disclosure.

FIG. 10A is a schematic diagram (1) illustrating a manufacturing method for the light emitting element 300 according to the first embodiment of the present disclosure.

FIG. 10B is a schematic diagram (2) illustrating the manufacturing method for the light emitting element 300 according to the first embodiment of the present disclosure.

FIG. 11 is a schematic diagram illustrating a manufacturing method for the light emitting element 300 according to a modification of the first embodiment of the present disclosure.

FIG. 12 is diagrams illustrating results of optical simulation for the first embodiment of the present disclosure and comparative examples.

FIG. 13 is an explanatory diagram illustrating a cross-sectional structure of the light emitting device 10 according to a second embodiment of the present disclosure.

FIG. 14 is an explanatory diagram (1) illustrating a cross-sectional structure of the light emitting device 10 according to a modification of the second embodiment of the present disclosure.

FIG. 15 is an explanatory diagram (2) illustrating cross-sectional structures of the light emitting device 10 according to modifications of the second embodiment of the present disclosure.

FIG. 16 is an explanatory diagram (3) illustrating a cross-sectional structure of the light emitting device 10 according to a modification of the second embodiment of the present disclosure.

FIG. 17 is an explanatory diagram (1) illustrating an example of a planar arrangement of the light emitting elements 300 according to the second embodiment of the present disclosure.

FIG. 18 is an explanatory diagram (2) illustrating an example of a planar arrangement of the light emitting elements 300 according to the second embodiment of the present disclosure.

FIG. 19A is a schematic view (1) illustrating a manufacturing method for the light emitting element 300 according to the second embodiment of the present disclosure.

FIG. 19B is a schematic view (2) illustrating the manufacturing method for the light emitting element 300 according to the second embodiment of the present disclosure.

FIG. 19C is a schematic view (3) illustrating the manufacturing method for the light emitting element 300 according to the second embodiment of the present disclosure.

FIG. 19D is a schematic view (4) illustrating the manufacturing method for the light emitting element 300 according to the second embodiment of the present disclosure.

FIG. 19E is a schematic view (5) illustrating the manufacturing method for the light emitting element 300 according to the second embodiment of the present disclosure.

FIG. 19F is a schematic view (6) illustrating the manufacturing method for the light emitting element 300 according to the second embodiment of the present disclosure.

FIG. 20 is a diagram illustrating an optical simulation model.

FIG. 21 is a diagram illustrating results of the optical simulation.

FIG. 22 is a graph illustrating a tendency of emission intensity with respect to a height of a side wall 310.

FIG. 23 is a graph illustrating a tendency of emission intensity with respect to a width of the side wall 310.

FIG. 24 is a graph illustrating a tendency of emission intensity with respect to a taper angle of the side wall 310.

FIG. 25 is an appearance view illustrating an example of an electronic device to which the light emitting device 10 according to an embodiment of the present disclosure is applicable.

FIG. 26 is an appearance view illustrating another example of the electronic device to which the light emitting device 10 according to an embodiment of the present disclosure is applicable.

FIG. 27 is an appearance view illustrating still another example of the electronic device to which the light emitting device 10 according to an embodiment of the present disclosure is applicable.

FIG. 28 is an external view illustrating still further another example of the electronic device to which the light emitting device 10 according to an embodiment of the present disclosure is applicable.

### DESCRIPTION OF EMBODIMENTS

Preferred embodiments of the present disclosure will be described in detail below with reference to the accompanying drawings. Note that in the present description and the drawings, component elements having substantially the same functional configurations are denoted by the same reference numerals, and redundant description thereof will be omitted. Furthermore, in the present description and the drawings, component elements having substantially the same functional configurations are distinguished by giving the same reference numerals followed by different alphabets, in some cases. However, when there is no need to particularly distinguish the component elements having substantially the same or similar functional configurations, the component elements are denoted by the same reference numerals alone.

In addition, the drawings referred to in the following description are drawings for description of the embodiments of the present disclosure and for promotion of understanding thereof, and the shapes, dimensions, ratios, and the like of the component elements illustrated in the drawings may be different from those of actual component elements, for ease of understanding. Furthermore, a light emitting device, component elements included in the light emitting device, and the like illustrated in the drawings can be appropriately changed in design in consideration of the following description and known techniques. Furthermore, in the following description, the vertical direction of a stacked structure of the light emitting device corresponds to a relative direction the light emitting device arranged so that light emitted from the light emitting device is directed from the bottom to the top, unless otherwise specified.

The shapes in the following description include not only geometrically defined shapes but also shapes having an allowable difference (error/distortion) in the operation of a light emitting element and a manufacturing process of the light emitting element, as shapes similar to the shapes.

Furthermore, in the following description of circuits (electrical connections), unless otherwise specified, the wording “electrically connected” means that a plurality of elements is connected to each other so that electricity (signal) is conducted. In addition, in the following description, the wording “electrically connected” includes not only directly and electrically connecting a plurality of elements but also indirectly and electrically connecting the plurality of elements via another element.

Note that the description will be given in the following order.
1. Light emitting device according to embodiment of present disclosure
1.1 Planar structure
1.2 Equivalent circuit of drive circuit unit
2. First Embodiment
2.1 Background
2.2 Overview of cross-sectional structure
2.3 Details of cross-sectional structure
2.4 Modification
2.5 Planar arrangement
2.6 Manufacturing method
2.7 Results of simulation
3. Second Embodiment
3.1 cross-sectional structure
3.2 Modifications
3.3 Planar arrangement
3.4 Manufacturing method
3.5 Results of simulation
4. Conclusion
5. Application examples
6. Supplementary notes

### 1. Light Emitting Device According to Embodiment of Present Disclosure

First, before describing the details of the embodiment of the present disclosure, a light emitting device according to an embodiment of the present disclosure will be described.

### 1.1 Planar Structure

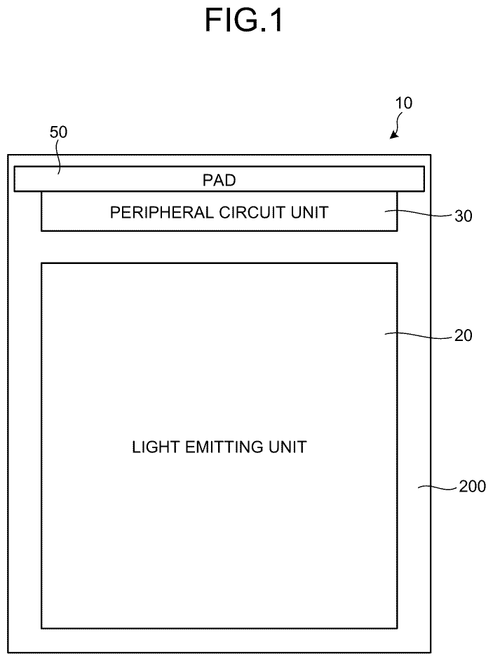

An example of a planar structure of a light emitting device 10 according to an embodiment of the present disclosure will be described with reference to FIG. 1. FIG. 1 is a cross-sectional view schematically illustrating the example of the planar structure of the light emitting device 10 according to the embodiment of the present disclosure. In the following description, an organic EL device will be described as the example of the light emitting device 10 of the present embodiment.

The light emitting device 10 according to the embodiment of the present disclosure is constituted by stacking a semiconductor substrate 100 and a semiconductor substrate 200 and bonding the semiconductor substrates 100 and 200 to each other. Note that the semiconductor substrates 100 and 200 may be, for example, single crystal silicon (Si) substrates or other semiconductor substrates such as silicon carbide (SiC) substrates. FIG. 1 illustrates a plan view of the light emitting device 10 when the light emitting device 10 is viewed from above (above a light emitting unit 20), in other words, a plan view of the semiconductor substrate 200 positioned on the upper side in the stack as viewed from above.

Specifically, as illustrated in FIG. 1, the semiconductor substrate 200 is mainly provided with the light emitting unit 20, a peripheral circuit unit 30, and a pad 50. Furthermore, the semiconductor substrate 100 may be provided with part of a drive circuit unit that includes a pixel transistor group including a plurality of pixel transistors that drive the light emitting unit 20. Hereinafter, details of blocks provided on the semiconductor substrate 200 of the light emitting device 10 according to the present embodiment will be described.

### (Light Emitting Unit 20)

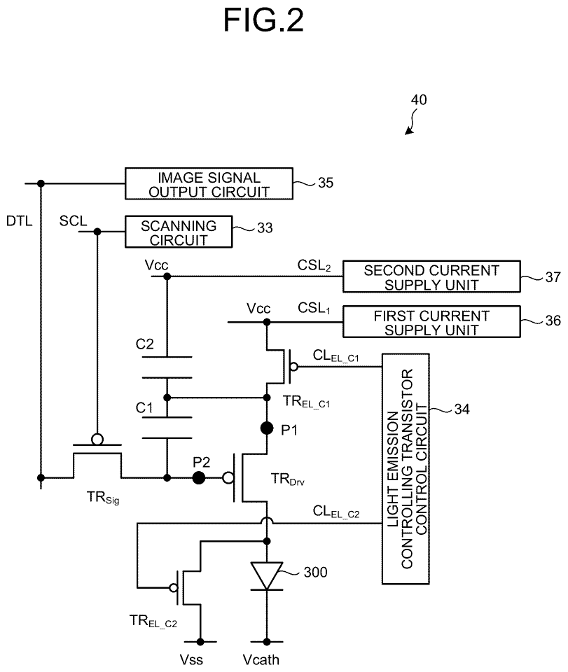

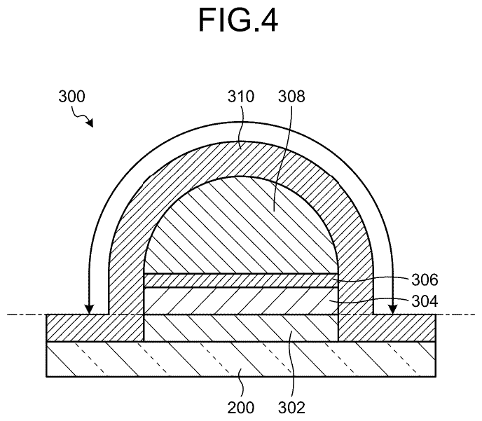

The light emitting unit 20 includes a plurality of light emitting elements 300 (see FIG. 2) arranged in a matrix in a horizontal direction and a vertical direction (row direction and column direction). Each of the light emitting elements 300 can be, for example, an organic electronic luminescent (EL) element (OLED) whose light emission luminance changes according to the magnitude of a supplied current. More specifically, each light emitting element 300 has a known configuration and structure including an anode electrode 302, a light emitting layer 304, a cathode electrode 306 (see FIG. 4), and the like. Furthermore, the light emitting layer has a structure in which, for example, a hole transport layer (not illustrated), an organic light emitting layer (not illustrated), and an electron transport layer (not illustrated) are stacked. Furthermore, a drive circuit block (the pixel transistor group) that drives each light emitting element 300 or the plurality of light emitting elements 300 may be provided. Note that one or a plurality of the drive circuit blocks constitutes a drive circuit unit 40 (see FIG. 2) which is described later.

Note that in the present embodiment, the light emitting device 10 may have a configuration for monochrome display or color display. Furthermore, for the configuration for color display, the plurality of light emitting elements 300 may include color filters 360 (see FIG. 4) having different colors or may include the light emitting layer 304 (see FIG. 4) emitting light of different colors.

### (Peripheral Circuit Unit 30)

As illustrated in FIG. 1, the peripheral circuit unit 30 is a circuit unit that is positioned around the light emitting unit 20 and supplies signal voltage or power supply voltage to the drive circuit unit 40 described above. Specifically, the peripheral circuit unit 30 can include, for example, a horizontal scanning circuit (not illustrated), a vertical scanning circuit (not illustrated), a gamma voltage generation circuit (not illustrated), a timing controller (not illustrated), a digital/analog (D/A) converter (not illustrated), an amplifier (not illustrated), an interface (not illustrated), and a memory (not illustrated). Furthermore, the peripheral circuit unit 30 may include a test circuit (not illustrated). In the following description, the horizontal scanning circuit corresponds to a scanning circuit 33 and a light emission controlling transistor control circuit 34, and the vertical scanning circuit corresponds to an image signal output circuit 35 (see FIG. 2).

### (Pad 50)

The pad 50 is a pad for electrically connecting a power supply circuit to the cathode electrode 306 (see FIG. 4) of the light emitting element 300 of the light emitting unit 20, or for electrically connecting the power supply circuit to various transistors to apply a voltage to the various transistors. The pad 50 is formed of, for example, a conductive material such as a metal film. The pad 50 may be provided between light emitting elements 300 in the light emitting unit 20.

Note that the example of the planar configuration of the light emitting device 10 according to the present embodiment is not limited to the example illustrated in FIG. 1, and may include, for example, another circuit unit or the like.

### 1.2 Equivalent Circuit of Drive Circuit Unit

Next, an equivalent circuit of the drive circuit unit 40 of the light emitting device 10 according to an embodiment of the present disclosure will be described with reference to FIG. 2. FIG. 2 is an equivalent circuit diagram of an example of a drive circuit unit 40 of the light emitting device 10 according to an embodiment of the present disclosure, and specifically, the equivalent circuit illustrated in FIG. 2 shows the drive circuit block (pixel transistor group) provided for each pixel (one light emitting element 300). In the following description, a 4Tr-2C circuit configuration having four transistors and two capacitors will be described as an example of the drive circuit block of the drive circuit unit 40, but the present embodiment is not limited thereto. In the present embodiment, for example, a 3Tr-2C circuit configuration having three transistors and two capacitors, a 4Tr-1C circuit configuration having four transistors and one capacitor, a 3Tr-1C circuit configuration having three transistors and one capacitor, and the like are applicable.

The drive circuit unit 40 is a circuit unit that drives the light emitting element 300 of the light emitting unit 20, and that is constituted by one or a plurality of drive circuit blocks illustrated in FIG. 2, as described above.

As illustrated in FIG. 2, the drive circuit unit 40 can include four transistors (pixel transistors) (drive transistor TR_{Drv}, image signal writing transistor TR_{Sig}, first light emission control transistor TR_{EL_C1}, and second light emission control transistor TR_{EL_C2}), two capacitors (first capacitor C1 and second capacitor C2), and various signal lines (scanning line SCL, data line DTL, first current supply line CSL₁, second current supply line CSL₂, first light emission control line CL_{EL_C1}, and second light emission control line CL_{EL_C2}). The drive circuit unit 40 includes a transistor group (the pixel transistor group) including the four transistors and two capacitors provided to correspond to each of the plurality of light emitting elements 300 constituting the light emitting unit 20.

The drive transistor TR_{Drv} is a transistor that controls a current flowing through the light emitting unit 20 to drive the light emitting element 300. The drive transistor TR_{Drv} has one of a source/drain that is connected to the anode of the light emitting unit 20, the other of the source/drain that is connected to one of a source/drain of the first light emission control transistor TR_{EL_C1}, and a gate that is connected to one of a source/drain of the image signal writing transistor TR_{Sig} and one electrode of the first capacitor C1.

The image signal writing transistor TR_{Sig} is a transistor that switches signal voltage (row selection signal) to perform row selection according to the signal voltage. The image signal writing transistor TR_{Sig} has the other of the source/drain that is connected to the image signal output circuit 35 via the data line DTL, and a gate that is connected to the scanning circuit 33 via the scanning line SCL.

The first light emission control transistor T_{REL_C1} is a transistor that switches power supply voltage (column selection signal) to perform column selection according to the power supply voltage. The first light emission control transistor TR_{EL_C1} has the other of the source/drain that is connected to a first current supply unit 36 via the first current supply line CSL₁, and a gate that is connected to the light emission controlling transistor control circuit 34 via the first light emission control line CL_{EL_C1}. Drive voltage V_{cc} is applied from the first current supply unit 36 to the other of the source/drain region of the first light emission control transistor TR_{EL_C1}.

The second light emission control transistor TR_{EL_C2} is a transistor that resets voltage (anode voltage) applied to the light emitting unit 20. The second light emission control transistor TR_{EL_C2} has one of a source/drain that is connected to the anode of the light emitting unit 20, the other of the source/drain that is connected to a reset voltage line Vₛₛ, and a gate that is connected to the light emission controlling transistor control circuit 34 via the second light emission control line CL_{EL_C2}.

The first capacitor C1 and the second capacitor C2 are connected in series to each other. The first capacitor C1 has one electrode that is connected to the gate of the drive transistor TR_{Drv}, and the one of the source/drain of the image signal writing transistor TR_{Sig}. The other electrode of the first capacitor C1 and one electrode of the second capacitor C2 are connected to the other of the source/drain of the drive transistor TR_{Drv} and the one of the source/drain of the first light emission control transistor TR_{EL_C1}. The second capacitor C2 has the other electrode that is connected to a second current supply unit 37 via the second current supply line CSL₂. Drive voltage V_{cc} is applied from the second current supply unit 37 to the other electrode of the second capacitor C2.

As described above, the light emitting element 300 has a configuration and structure according to an embodiment of the present disclosure described later that includes the anode electrode 302, the light emitting layer 304, the cathode electrode 306 (see FIG. 4), and the like. Then, the anode electrode 302 is connected to the one of the source/drain of the drive transistor TR_{Drv} and the one of the source/drain of the second light emission control transistor TR_{EL_C2}. The cathode electrode 306 is connected to a power supply line V_{cath}.

Furthermore, in the present embodiment, the drive transistor TR_{Drv}, the image signal writing transistor TR_{Sig}, the first light emission control transistor TR_{EL_C1}, and the second light emission control transistor TR_{EL_C2} include, for example, a p-channel metal oxide semiconductor field effect transistor (MOSFET), and are formed in n-type wells formed in p-type silicon semiconductor substrates.

Note that the example of the circuit configuration of the drive circuit unit 40 according to the present embodiment is not limited to the example illustrated in FIG. 2, as described above.

### 2. First Embodiment

### 2.1 Background

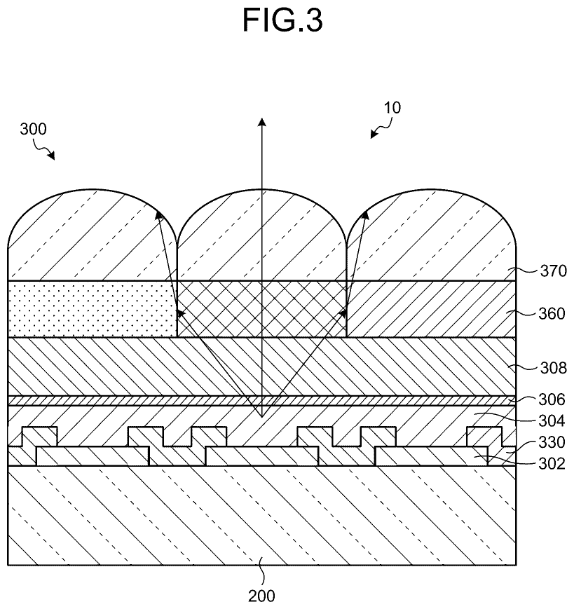

First, before description of a first embodiment of the present disclosure, a background to create the first embodiment of the present disclosure by the present inventors will be described with reference to FIG. 3. FIG. 3 is an explanatory diagram illustrating the background of the first embodiment of the present disclosure.

FIG. 3 illustrates the light emitting device 10 of top emission type that extracts white light from the light emitting layer 304 of light emitting elements 300 positioned on the lower side, to the outside via color filters 360 positioned on the upper side. According to the top emission type, light can be efficiently extracted, consume low power, and long life can be achieved. Furthermore, according to the structure illustrated in FIG. 3, light is condensed by lenses (on chip lenses) 370 provided on the color filters 360, further improving light extraction efficiency.

However, as a result of intensive studies on the light emitting device 10 in order to further improve the light extraction efficiency, the present inventors have found that part of light emitted from one light emitting layer 304 passes through not a color filter 360 positioned immediately above the light emitting layer 304 but an adjacent color filter 360 and is condensed to a lens 370 positioned immediately above the adjacent color filter. In such a case, light cannot be condensed by a desired lens 370, and therefore, the light emitting device 10 is limited in improvement of light extraction efficiency, causing a problem of color mixing or the like. In particular, miniaturization of the light emitting elements 300 may cause concern that the above-described phenomenon remarkably occurs.

Therefore, in view of such a situation, the present inventors have created the first embodiment of the present disclosure to further improve the light extraction efficiency. Hereinafter, details of the first embodiment of the present disclosure created by the present inventors will be described.

### 2.2 Overview of Cross-Sectional Structure

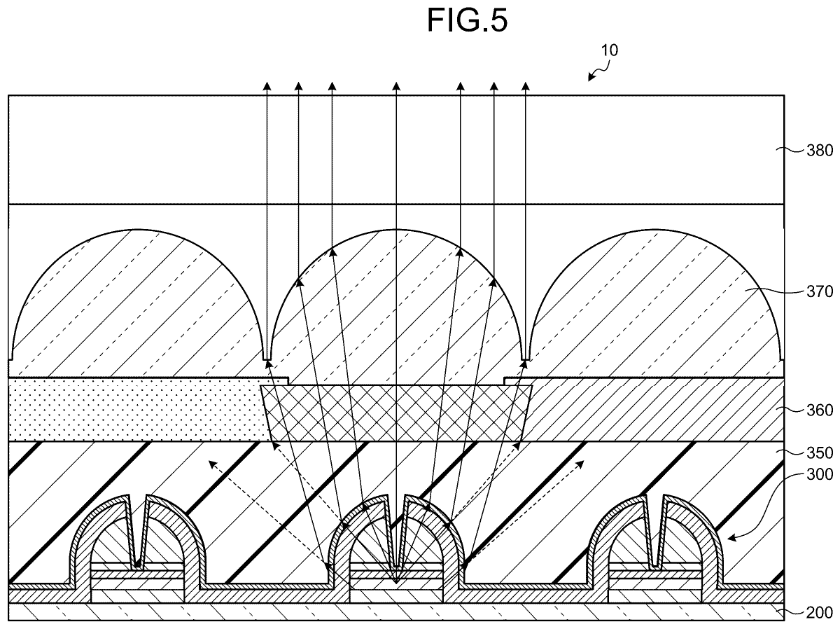

First, an overview of cross-sectional structures of a light emitting elements 300 and the light emitting device 10 according to the present embodiment will be described with reference to FIGS. 4 and 5. FIG. 4 is an explanatory diagram illustrating an overview of a cross-sectional structure of the light emitting element 300 according to the present embodiment, and specifically corresponds to a cross-section of the light emitting element 300 taken in a film thickness direction of the semiconductor substrate 200. Furthermore, FIG. 5 is an explanatory diagram illustrating an overview of the cross-sectional structure of the light emitting device 10 according to the present embodiment, and specifically corresponds to a cross-section of the light emitting device 10 taken in a film thickness direction of the semiconductor substrate 200.

As illustrated in FIG. 4, the light emitting element 300 according to the present embodiment mainly includes the anode electrode (first electrode) 302, the light emitting layer 304, the cathode electrode (second electrode) 306, a protective film (second protective film) 308, and a side wall 310, which are provided on the semiconductor substrate 200. Hereinafter, details of each of the elements of the light emitting element 300 according to the present embodiment will be sequentially described.

### (Anode Electrode 302)

The anode electrode 302 is provided on the semiconductor substrate 200. For example, the anode electrode 302 can be a single-layer film made of any one of metals and metal oxides, or a multi-layer film made of a plurality of materials selected from the metals and metal oxides. Specifically, the metals can include, for example, chromium (Cr), gold (Au), platinum (Pt), nickel (Ni), copper (Cu), molybdenum (Mo), titanium (Ti), tantalum (Ta), aluminum (Al), magnesium (Mg), iron (Fe), tungsten (W), silver (Ag), and the like, alloys thereof (e.g., AlCu etc.), or alloys thereof with carbide (e.g., ACX being an alloy of aluminum, carbon, and magnesium, etc.). Furthermore, the metal oxides can include an indium tin oxide (ITO), an indium zinc oxide (IZO), a zinc oxide (ZnO), a copper oxide (CuO), and a titanium oxide (TiO₂).

### (Light Emitting Layer 304)

The light emitting layer 304 is provided on the anode electrode 302 described above and held between the anode electrode 302 and the cathode electrode 306 which is described later, in which electrons and holes injected from these electrodes are bound again in the light emitting layer 304, and light is allowed to be emitted. Furthermore, the light emitting layer 304 has a structure in which, for example, a hole transport layer (not illustrated), an organic light emitting layer (not illustrated), and an electron transport layer (not illustrated) are stacked. Furthermore, the light emitting layer 304 is formed of an organic material, and configured to emit any of white light, blue light, green light, and red light by appropriately selecting a material or stacked structure.

### (Cathode Electrode 306)

The cathode electrode 306 is made of a conductive material that transmits light, and is provided on the light emitting layer 304. For example, the cathode electrode 306 can be a single-layer film made of any one of metals and metal oxides, or a multi-layer film made of a plurality of materials selected from the metals and metal oxides. Specifically, the metals include, for example, at least one metal element selected from the group consisting of magnesium (Mg), aluminum (Al), silver (Ag), calcium (Ca), and sodium (Na). Furthermore, the metal oxides can include an indium tin oxide (ITO), an indium zinc oxide (IZO), a zinc oxide (ZnO), a copper oxide (CuO), and a titanium oxide (TiO₂).

### (Protective Film 308)

The protective film 308 is a transparent film that protects the anode electrode 302, the light emitting layer 304, and the cathode electrode 306. The protective film 308 provided on the cathode electrode 306 has a shape having, for example, a substantially semicircular cross-section with an upper arc, as illustrated in FIG. 4. Specifically, the protective film 308 is preferably a transparent single-layer film or multi-layer film that is formed of an inorganic material having low hygroscopicity. For example, the protective film 308 preferably includes at least one selected from the group consisting of a silicon oxide (SiO₂) (refractive index of 1.5 or less), a silicon nitride (SiN) (refractive index of 2 or less), a silicon oxynitride (SiON) (refractive index of 1.7 or less), a titanium oxide (TiO₂) (refractive index of 2.5 or less), and an aluminum oxide (Al₂O₃) (refractive index of 1.6 or less). For example, the protective film 308 is made of silicon nitride (SiN) having a height or film thickness of approximately 0.5 μm to 5 μm.

### (Side Wall 310)

The side wall 310 is provided to cover at least part of a side surface of a stack including the anode electrode 302, the light emitting layer 304, the cathode electrode 306, and the protective film 308. Furthermore, the side wall 310 is formed of a transparent material that has a refractive index different from that of a material forming a protective film (first protective film) 350 (see FIG. 5) which is described later. In addition, as illustrated in FIG. 4, the side wall 310 is preferably formed to have a lens-shaped (substantially semicircular) cross-section protruding outside the stack. In the present embodiment, providing the side wall 310 configured as described above makes it possible to refract light at an interface between the side wall 310 and the protective film 350 due to a difference in refractive index. Therefore, according to the present embodiment, the side wall 310 is made to function as a lens so that the light emitted from the light emitting layer 304 can be guided in a desired direction.

Note that in the present embodiment, an arc portion of the interface between the side wall 310 and the protective film 350 is defined as a lens portion of the side wall 310, in FIG. 4. In other words, the lens portion of the side wall 310 means a range of the side wall 310 indicated by an arcuate arrow, in FIG. 4.

In the present embodiment, as illustrated in the cross-sectional view of FIG. 4, the lens portion of the side wall 310 is provided to extend from a position above an upper surface of the cathode electrode 306 to a position below an upper surface of the light emitting layer 304, downward in a stacking direction of the stack. Specifically, the end of the lens portion (position indicated by a broken line in FIG. 4) is positioned below the upper surface of the light emitting layer 304. In other words, the side wall 310 is provided to cover the entire end surface of the cathode electrode 306 and part of an end surface of the light emitting layer 304.

Furthermore, in the present embodiment, as illustrated in the cross-sectional view of FIG. 4, the lens portion of the side wall 310 is preferably provided to extend below a lower surface of the light emitting layer 304 or a position flush with the lower surface, downward in the stacking direction of the stack. Specifically, the end of the lens portion (a position indicated by a broken line in FIG. 4) is positioned below the lower surface of the light emitting layer 304 or positioned to be flush with the lower surface. In other words, the lens portion of the side wall 310 is preferably provided to extend to a position below an upper surface of the anode electrode 302. In this configuration, the side wall 310 is provided to cover the entire end surface of the light emitting layer 304 and part of an end surface of the anode electrode 302.

In addition, in the present embodiment, as illustrated in the cross-sectional view of FIG. 4, the lens portion of the side wall 310 is preferably provided to extend to cover the protective film 308, upward in the stacking direction of the stack.

In addition, the side wall 310 is preferably formed of a transparent material having a refractive index higher than that of the material forming the protective film 350 which is described later, a refractive index equal to or lower than that of the material forming the protective film 308, and a refractive index of 2.5 or less, and more preferably, a refractive index of 1.6 or less. Specifically, the side wall 310 is preferably a single-layer film or multi-layer film that is formed of an organic or inorganic material having low hygroscopicity. For example, the side wall 310 preferably includes at least one selected from the group consisting of an organic material (refractive index of approximately 1.8), a silicon oxide (SiO₂) (refractive index of 1.5 or less), a silicon nitride (SiN) (refractive index of 2 or less), a silicon oxynitride (SiON) (refractive index of 1.7 or less), a titanium oxide (TiO₂) (refractive index of 2.5 or less), an aluminum oxide (Al₂O₃) (refractive index of 1.6 or less), and an indium zinc oxide (IZO) (refractive index of 2.0). Specifically, the side wall 310 is made of, for example, silicon nitride (SiN) having a film thickness of 0.1 μm to 1.0 μm.

In the present embodiment, providing the side wall 310 configured as described above makes it possible to guide light emitted from the light emitting layer 304 in a desired direction (see FIG. 5). Accordingly, in the present embodiment, it is possible to prevent part of light emitted from the light emitting layer 304 from passing through not the color filter 360 positioned immediately above the light emitting layer 304 but the adjacent color filter 360 and from being condensed to the lens 370 positioned immediately above the color filter.

Therefore, according to the present embodiment, light emitted from the light emitting layer 304 is allowed to be condensed by the desired lens 370, thus, improving the light extraction efficiency of the light emitting device 10, further suppressing the occurrence of a problem such as color mixing.

Note that the light emitting element 300 according to the present embodiment is not limited to the cross-sectional structure as illustrated in FIG. 4, and for example, other elements may be added.

Next, an overview of a cross-sectional configuration of the light emitting device 10 according to the present embodiment will be described with reference to FIG. 5. As illustrated in FIG. 5, the light emitting device 10 according to the present embodiment mainly includes a plurality of light emitting elements 300 that is provided on the semiconductor substrate 200, the protective film (first protective film) 350 that covers the light emitting elements 300, the color filters 360 that are provided on the protective film 350, the lenses 370 that is provided on the color filters 360, and opposed glass 380 that are provided on the lenses 370. Hereinafter, details of each of the elements of the light emitting device 10 according to the present embodiment will be sequentially described. Note that in FIG. 5, a cross-sectional structure of each of the light emitting elements 300 is different from the structure illustrated in FIG. 4, but details of the difference will be described later.

### (Protective Film 350)

The protective film 350 is a film that protects the plurality of light emitting elements 300, and is provided over the plurality of light emitting elements 300 and between the light emitting elements 300 adjacent to each other. Specifically, the protective film 350 can include at least one of a transparent thermosetting resin and a transparent ultraviolet curable resin, and is formed of a material having a refractive index of approximately 1.2 to 2.0. Specifically, the protective film 350 is formed of, for example, an acrylic resin or a polyimide resin.

### (Color Filter 360)

Each of the color filters 360 is provided on the protective film 350 and below each of the lenses 370 which are described later so as to correspond to the light emitting elements 300, and is configured to selectively transmit blue light, green light, or red light. Note that in the present embodiment, when the light emitting layer 304 described above is configured to emit blue light, green light, or red light, the color filter 360 may not be provided.

### (Lens 370)

The lenses 370 are each provided above the protective film 350 so as to correspond to each light emitting element 300. The lens 370 can be formed of, for example, a silicon nitride (SiN) or a resin-based material such as a styrene resin, acrylic resin, styrene-acrylic copolymer resin, or a siloxane resin.

### (Opposed Glass 380)

The opposed glass 380 is a layer that is provided over the lens 370 to protect the light emitting elements 300, the color filters 360, and the lenses 370, and can be formed of glass or the like.

Furthermore, in the present embodiment, as illustrated in FIG. 5, the side wall 310 described above can be provided to be connected to the side wall 310 of another adjacent light emitting element 300. Note that in the present embodiment, the side wall 310 is provided to be connected to a side wall 310 of another adjacent light emitting element 300, but is not limited to this configuration, and may be provided to be separated from the side wall 310 of the another adjacent light emitting element 300.

In the present embodiment, as illustrated in FIG. 5, the interface between the side wall 310 having an arcuate shape and the protective film 350 functions as a lens due to a difference in refractive index, and therefore, light emitted from a light emitting layer 304 is allowed to be guided to a color filter 360 and a lens 370 that are positioned immediately above the light emitting layer 304. Accordingly, in the present embodiment, it is possible to prevent part of light emitted from the light emitting layer 304 from passing through not the color filter 360 positioned immediately above the light emitting layer 304 but the adjacent color filter 360 and from being condensed to the lens 370 positioned immediately above the color filter. Therefore, according to the present embodiment, light emitted from the light emitting layer 304 is allowed to be condensed by the desired lens 370, thus, improving the light extraction efficiency of the light emitting device 10, further suppressing the occurrence of a problem such as color mixing.

Note that the light emitting device 10 according to the present embodiment is not limited to the cross-sectional structure as illustrated in FIG. 5, and for example, other elements may be added.

### 2.3 Details of Cross-Sectional Structure

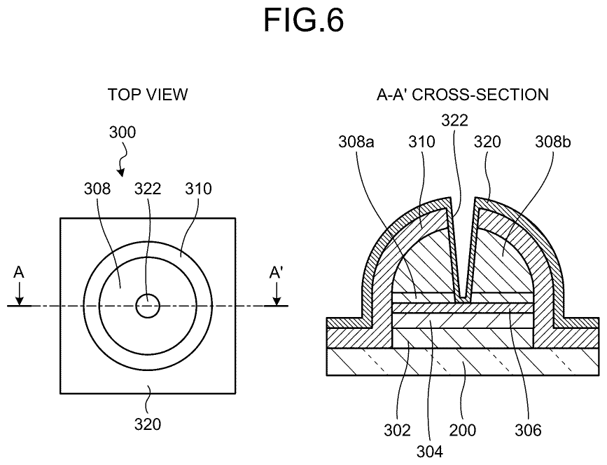

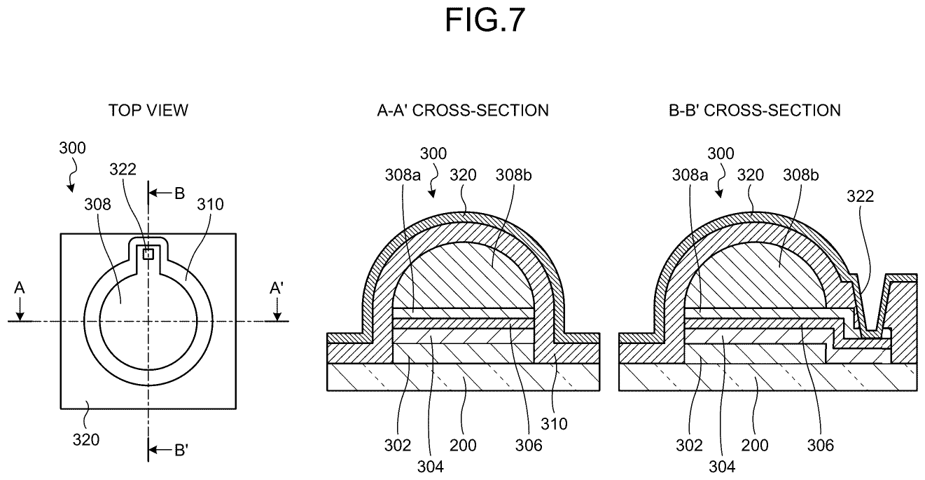

First, the structure of the light emitting element 300 according to the present embodiment will be described in detail with reference to FIGS. 6 and 7. FIGS. 6 and 7 are each an explanatory diagram illustrating details of a structure of the light emitting element 300 according to the present embodiment, and specifically, a top view of the light emitting element 300 is illustrated on the left side, and a cross-sectional view of the light emitting element 300 is illustrated on the right side.

The right side of FIG. 6 illustrates the cross-sectional view of the light emitting element 300 taken along line A-A′ in the top view illustrated on the left side of FIG. 6. As illustrated in FIG. 6, the light emitting element 300 according to the present embodiment has a similar structure to the cross-sectional structure described with reference to FIG. 4, but is different in that the protective film 308 (308a and 308b) made of a multi-layer film, a common electrode 320, and a hole (contact hole) 322 are provided. Here, the protective film 308 (308a and 308b), the common electrode 320, and the hole 322 will be described, and description of elements common to those of FIG. 4 will be omitted.

### (Protective Film 308)

In the structure illustrated in FIG. 6, the protective film 308 includes a stack of the protective film 308a and the protective film 308b, and the protective film 308b on the upper side has a substantially semicircular cross-section with an upper arc.

### (Common Electrode 320)

The common electrode 320 is an electrode electrically connected to the cathode electrode 306, and mutual connection of the common electrodes 320 of the light emitting elements 300 adjacent to each other makes it possible to function as an electrode common to the plurality of light emitting elements 300. Such a structure of the common electrode 320 makes it possible to apply a uniform voltage to the cathode electrodes 306 of the light emitting elements 300, suppressing variations in emission intensity (uneven light emission) of the light emitting elements 300. Specifically, the common electrode 320 is provided to cover the side wall 310 covering the protective film 308 and the like, and further provided to cover an inner wall of the hole 322 that penetrates the side wall 310, the protective film 308b, and the protective film 308a to expose the cathode electrode 306.

In addition, the common electrode 320 is preferably formed of a transparent conductive material that has a refractive index higher than that of the material forming the protective film 350, and has a refractive index equivalent to that of the material forming the side wall 310. For example, the common electrode 320 can be formed of magnesium (Mg), silver (Ag), aluminum (Al), an indium tin oxide (ITO), an indium zinc oxide (IZO), or the like.

### (Hole 322)

As described above, the hole 322 is provided to penetrate the side wall 310, the protective film 308b, and the protective film 308a to expose the cathode electrode 306. In FIG. 6, the hole 322 is provided at the center of the light emitting element 300, but in the present embodiment, the hole 322 is not limited to being provided at the center of the light emitting element 300, and may be provided to be appropriately shifted from the center of the light emitting element 300, for example, according to the position of the light emitting element 300 in the light emitting unit 20. Furthermore, the inside of the hole 322 may be filled with a material having a high refractive index.

Furthermore, in the present embodiment, the light emitting element 300 may have a cross-sectional structure as illustrated in FIG. 7. The center of FIG. 7 illustrates a cross-sectional view of the light emitting element 300 taken along line A-A′ in a top view illustrated on the left side of FIG. 7, and the right side of FIG. 7 illustrates a cross-sectional view of the light emitting element 300 taken along line B-B′ in the top view illustrated on the left side of FIG. 7.

As illustrated in FIG. 7, in the light emitting element 300 according to the present embodiment, instead of forming the hole 322 at the center of the light emitting element 300, the hole 322 is formed at an end of the light emitting element 300. Specifically, in the structure of FIG. 7, the cathode electrode 306 is extended to the end of the light emitting element 300, and the hole 322 penetrating the side wall 310 is formed so as to expose the extended portion of the cathode electrode 306. Furthermore, the common electrode 320 is provided to cover the side wall 310 and the inner wall of the hole 322.

Note that the cross-sectional structure of the light emitting element 300 according to the present embodiment is not limited to the examples illustrated in FIGS. 6 and 7, and can be appropriately deformed.

### 2.4 Modification

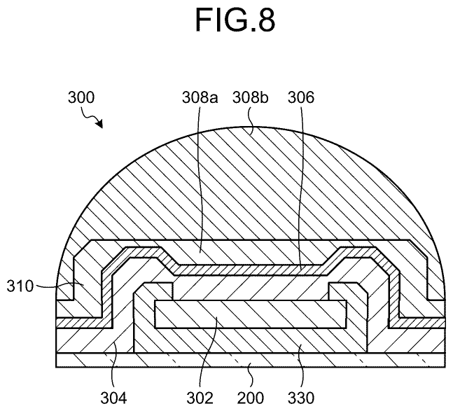

Furthermore, in the present embodiment, the structure of the light emitting element 300 can be further changed. Therefore, a modification of the present embodiment will be described with reference to FIG. 8. FIG. 8 is an explanatory diagram illustrating the light emitting element 300 according to a modification of the present embodiment.

As illustrated in FIG. 8, the light emitting element 300 according to the present modification mainly includes an isolation film 330 that is provided on the semiconductor substrate 200, the anode electrode 302 that is provided to be surrounded by the isolation film 330, the light emitting layer 304 that is provided to cover the isolation film 330 and the anode electrode 302, the cathode electrode 306, and the protective films 308a and 308b. Hereinafter, details of each of the elements of the light emitting element 300 according to the present modification will be sequentially described.

The isolation film 330 is a film that is provided on the semiconductor substrate 200 to define the light emitting element 300, and specifically, is provided to surround the anode electrode 302. The isolation film 330 can be formed of an organic or inorganic material. Specifically, examples of the organic material include a polyimide resin and an acrylic resin. Furthermore, examples of the inorganic material include a silicon oxide (SiO₂), a silicon nitride (SiN), a silicon oxynitride (SiON), a titanium oxide (TiO₂), and an aluminum oxide (Al₂O₃).

Furthermore, in the present modification, the anode electrode 302 provided to be surrounded by the isolation film 330 may have a flat upper surface, or may have a substantially recessed cross-section opened upward, as illustrated in FIG. 8. The anode electrode 302 having such a recessed cross-section is allowed to efficiently guide light toward the lens 370.

Furthermore, in the present modification, the cathode electrode 306 is provided to be connected to a cathode electrode 306 of an adjacent light emitting element 300.

In the present modification, the light emitting layer 304, the cathode electrode 306, and the protective film 308a are provided to cover the isolation film 330 and the anode electrode 302, along the shape of the isolation film 330 and anode electrode 302. In addition, the protective film 308b is provided to cover the protective film 308a, and has a substantially semicircular cross-section with an upper arc.

Note that the cross-sectional structure of the light emitting element 300 according to the present modification is not limited to the example illustrated in FIG. 8, and can be appropriately changed.

### 2.5 Planar Arrangement

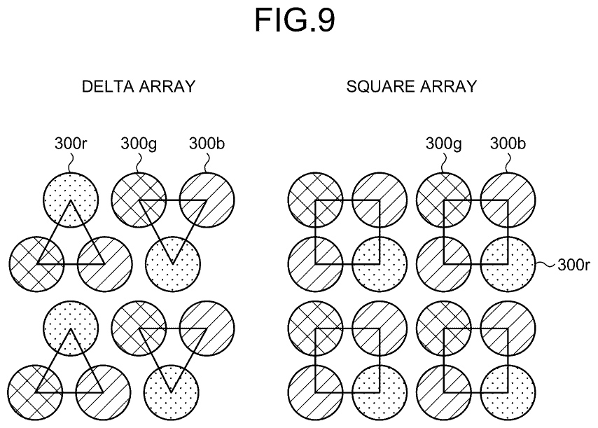

Next, an example of a planar arrangement of the light emitting elements 300 according to an embodiment of the present disclosure will be described with reference to FIG. 9. FIG. 9 is an explanatory diagram illustrating an example of the planar arrangement of the light emitting elements 300 according to the present embodiment.

As described above, the respective light emitting elements 300 according to the present embodiment are configured to emit red light, green light, and blue light. Then, as illustrated in FIG. 9, light emitting elements 300b (blue light), 300g (green light), and 300r (red light) that emit light of different colors are configured to be arranged in a square array (rectangular shape), a delta array (triangular shape), or the like, on the light emitting unit 20.

Note that the light emitting elements 300b, 300g, and 300r according to the present embodiment are not limited to the arrangements as illustrated in FIG. 9, and another arrangement can be selected.

### 2.6 Manufacturing Method

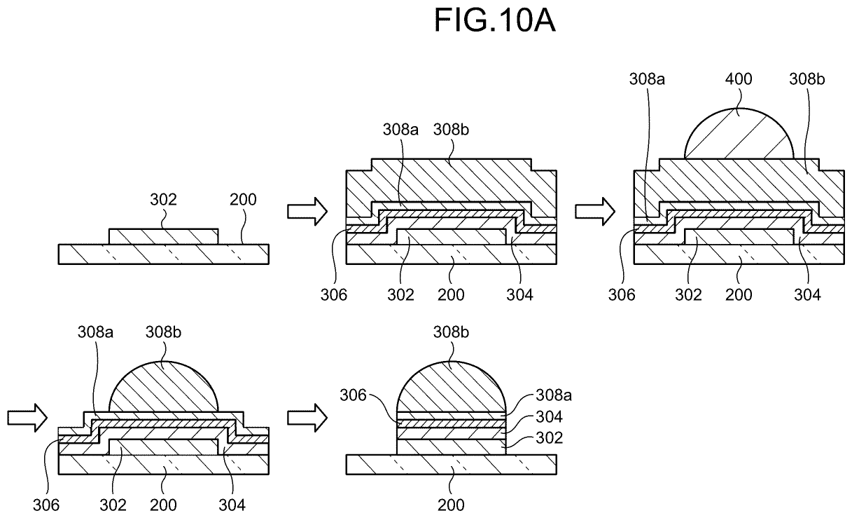

Next, a manufacturing method for the light emitting element 300 according to the present embodiment will be described with reference to FIGS. 10A and 10B. FIGS. 10A and 10B are each a schematic diagram illustrating the manufacturing method for the light emitting element 300 according to the present embodiment.

First, as illustrated on an upper left side of FIG. 10A, the anode electrode 302 is formed on the semiconductor substrate 200. The anode electrode 302 can be formed of, for example, aluminum (Al), an aluminum copper alloy (AlCu), an aluminum titanium alloy (AlTi), ACX that is an alloy of aluminum, carbon, and magnesium, an indium tin oxide (ITO), or the like.

Next, as illustrated in the second image from the left on the upper side in FIG. 10A, the light emitting layer 304 made of an organic material, the cathode electrode 306 made of an indium zinc oxide (IZO), a magnesium silver alloy (MgAg), or the like, and the protective films 308a and 308b made of a silicon nitride (SiN) or the like having a film thickness of approximately 0.5 μm to 5 μm are sequentially formed on the anode electrode 302. At this time, the films can be formed using a chemical vapor deposition method (CVD method) or the like.

Then, the protective film 308b is processed into a lens shape. First, as illustrated in the upper right side in FIG. 10A, a spherical resist 400 is formed on the protective film 308b by using a reflow method or gray tone mask. Furthermore, etching the protective film 308b so as to transfer the shape of the resist 400 to the protective film 308b, and therefore, the protective film 308b having the lens shape can be obtained as illustrated on the lower left side of FIG. 10A.

Furthermore, as illustrated in a lower right side of FIG. 10A, etching is entirely performed by an isotropic etching method, thereby processing from the protective film 308b to the anode electrode 302. At this time, the end surface of the light emitting layer 304 is preferably etched to be flush with the end surface of the anode electrode 302 or to be positioned inward from the end surface of the anode electrode 302. Furthermore, in the present embodiment, processing up to the anode electrode 302 by the etching described above makes it possible to provide the side wall 310 to entirely cover the end surface of the light emitting layer 304.

Next, in order to suppress deterioration of the light emitting layer 304, the side wall 310 is formed. As illustrated on the right side of FIG. 10B, silicon nitride (SiN) or the like having a film thickness of approximately 0.1 μm to 1.0 μm is formed by using CVD or the like. In order to suppress the deterioration of the light emitting layer 304, the formation of the side wall 310 is preferably performed in-situ along with the processing step using the etching described above.

Then, as illustrated at the center in FIG. 10B, a resist 402 is formed so as to cover the light emitting element 300, and the hole 322 is formed in the side wall 310 and protective films 308a and 308b by using photolithography, etching, or the like. Next, as illustrated on the right side in FIG. 10B, a film of magnesium (Mg), silver (Ag), aluminum (Al), indium zinc oxide (IZO), indium tin oxide (ITO), or the like is formed by sputtering or the like to form the common electrode 320. Furthermore, although not illustrated here, the protective film 350, the lens 370, and the like are further formed.

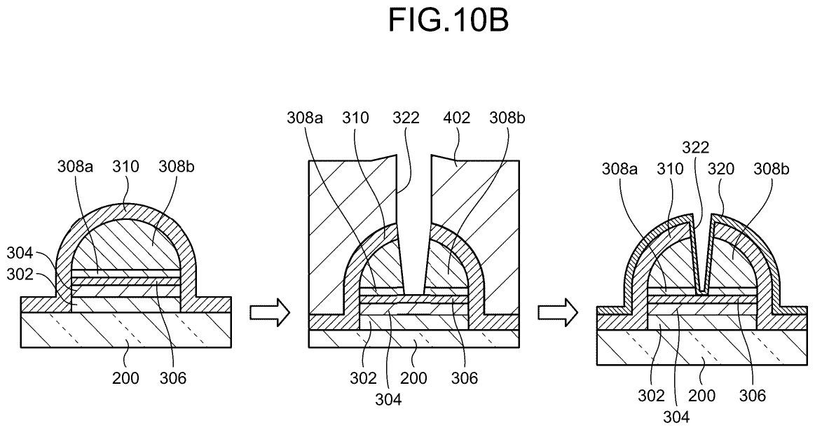

Furthermore, a manufacturing method for the light emitting element 300 according to a modification of the present embodiment will be described with reference to FIG. 11. FIG. 11 is a schematic diagram illustrating the manufacturing method for the light emitting element 300 according to the modification of the present embodiment.

First, as illustrated in an upper left side of FIG. 11, after the isolation film 330 is formed on the semiconductor substrate 200, a recessed portion is formed in the isolation film 330, and the anode electrode 302 is formed in the recessed portion. At this time, a trench is formed 200 nm to 1000 nm deeper than a lower surface of the anode electrode 302 and therefore, the isolation film 330 is divided for each light emitting element 300. Furthermore, the light emitting layer 304, the cathode electrode 306, and the protective films 308a and 308b are sequentially formed on the anode electrode 302. At this time, the protective film 308b is formed so as to have a film thickness of 500 nm to 5000 nm.

Furthermore, as illustrated at the upper center of FIG. 11, the protective films 308a and 308b are sequentially formed on the cathode electrode 306. At this time, the protective film 308b is formed to have a film thickness of 500 nm to 5000 nm.

Then, as illustrated on the upper right side of FIG. 11, a spherical resist 404 is formed on the protective film 308b by using the reflow method or gray tone mask. Furthermore, etching the protective film 308b so as to transfer the shape of the resist 404 to the protective film 308b, and therefore, the protective film 308b having the lens shape can be obtained as illustrated on the lower side of FIG. 11. Furthermore, although not illustrated here, the protective film 350, the lens 370, and the like are further formed.

Note that the light emitting elements 300 according to the present embodiment and the present modification are formed by, but are not limited to, the manufacturing method as illustrated in FIGS. 10A, 10B, and 11, and the process thereof may be appropriately changed.

### 2.7 Results of Simulation

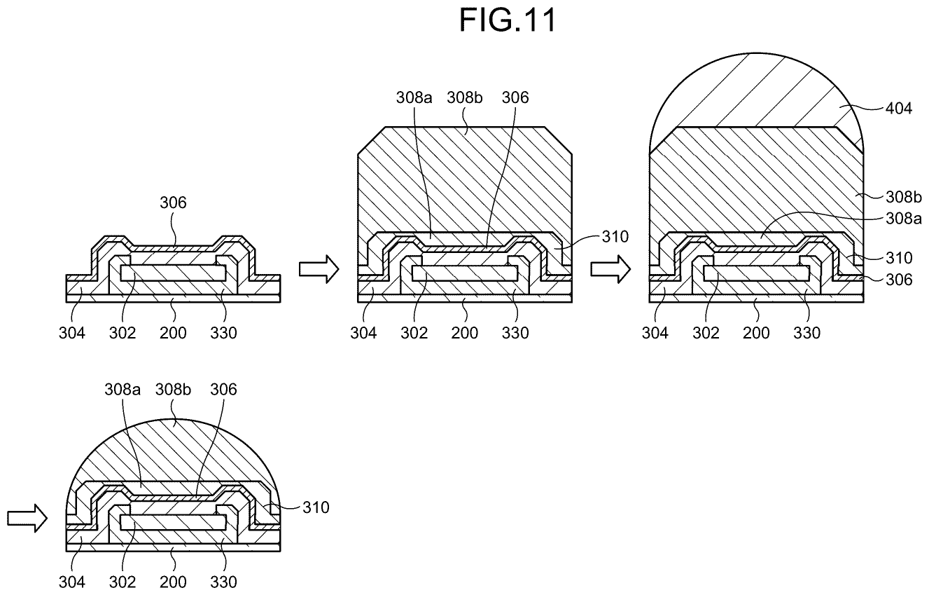

In order to verify the effects of the present embodiment, the present inventors performed an optical simulation. Hereinafter, results of the optical simulation for the present embodiment will be described with reference to FIG. 12. FIG. 12 is diagrams illustrating the results of the optical simulation for the present embodiment and comparative examples.

A result of the simulation illustrated on the right side of FIG. 12 is a result that is obtained from the structure according to the present embodiment. In addition, a result of the simulation for a structure 2 illustrated at the center of FIG. 12 is a result that is obtained when the lens portion of the side wall 310 does not extend to a position below the upper surface of the anode electrode 302, as a comparative example to the present embodiment. Furthermore, a result of the simulation for a structure 1 illustrated on the left side of FIG. 12 is a result that is obtained when the side wall 310 is not provided, as a comparative example to the present embodiment.

As can be seen from FIG. 12, in the structure according to the present embodiment, light from the light emitting layer 304 is guided immediately above, as compared with the structures 1 and 2 as the comparative examples.

As described above, in the present embodiment, the interface between the side wall 310 having the arcuate shape and the protective film 350 functions as the lens due to a difference in refractive index, and therefore, light emitted from a light emitting layer 304 is allowed to be guided to a color filter 360 and a lens 370 that are positioned immediately above the light emitting layer 304. Accordingly, in the present embodiment, it is possible to prevent part of light emitted from the light emitting layer 304 from passing through not the color filter 360 positioned immediately above the light emitting layer 304 but the adjacent color filter 360 and from being condensed to the lens 370 positioned immediately above the color filter. Therefore, according to the present embodiment, light emitted from the light emitting layer 304 is allowed to be condensed by the desired lens 370, thus, improving the light extraction efficiency of the light emitting device 10, further suppressing the occurrence of a problem such as color mixing.

### 3. Second Embodiment

### 3.1 Cross-Sectional Structure

Similarly to the first embodiment described above, a second embodiment of the present disclosure also aims to further improve the light extraction efficiency of the light emitting device 10. Hereinafter, details of the second embodiment of the present disclosure created by the present inventors will be described.

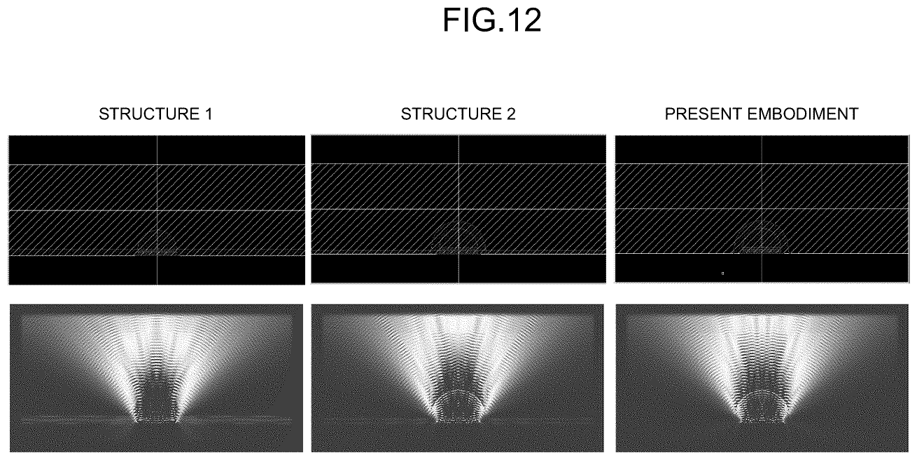

A cross-sectional structure of the light emitting device 10 according to the present embodiment will be described with reference to FIG. 13. FIG. 13 is an explanatory diagram illustrating the cross-sectional structure of the light emitting device 10 according to the present embodiment, and specifically corresponds to a cross-section of the light emitting device 10 taken in a film thickness direction of the semiconductor substrate 200.

As illustrated in FIG. 13, the light emitting device 10 according to the present embodiment mainly includes, as in the first embodiment described above, a plurality of light emitting elements 300 that is provided on the semiconductor substrate 200, the protective film (first protective film) 350 that covers the light emitting elements 300, the color filters 360 that are provided on the protective film 350, and the lenses 370 that are provided on the color filters 360. Note that the protective film 350, the color filters 360, and the lenses 370 are similar to those of the first embodiment described above, and thus detailed description thereof will be omitted here.

Furthermore, as illustrated in FIG. 13, each of the light emitting elements 300 according to the present embodiment mainly includes the anode electrode (first electrode) 302, the light emitting layer 304, the cathode electrode (second electrode) 306, a protective film (second protective film) 308, and a side wall 310, the common electrode 320, and the isolation film 330, which are provided on the semiconductor substrate 200. Hereinafter, details of each of the elements of the light emitting element 300 according to the present embodiment will be sequentially described.

### (Anode Electrode 302)

The anode electrode 302 is provided on the semiconductor substrate 200. For example, the anode electrode 302 can be a single-layer film made of any one of metals and metal oxides, or a multi-layer film made of a plurality of materials selected from the metals and metal oxides. Note that examples of materials for forming the anode electrode 302 are similar to those of the anode electrode 302 of the first embodiment, and therefore, description thereof is omitted here.

### (Light Emitting Layer 304)

The light emitting layer 304 is provided on the anode electrode 302 described above and held between the anode electrode 302 and the cathode electrode 306, in which electrons and holes injected from these electrodes are bound again in the light emitting layer 304, and light is allowed to be emitted. Furthermore, the light emitting layer 304 is formed of an organic material, and configured to emit any of white light, blue light, green light, and red light by appropriately selecting a material or stacked structure.

### (Cathode Electrode 306)

The cathode electrode 306 is made of a conductive material that transmits light, and is provided on the light emitting layer 304. For example, the cathode electrode 306 can be a single-layer film made of any one of metals and metal oxides, or a multi-layer film made of a plurality of materials selected from the metals and metal oxides. Note that examples of materials for forming the cathode electrode 306 are similar to those of the cathode electrode 306 of the first embodiment, and therefore, description thereof is omitted here.

### (Protective Film 308)

The protective film 308 is a transparent film that protects the anode electrode 302, the light emitting layer 304, and the cathode electrode 306. In the present embodiment, the protective film 308 has the hole 322 provided to penetrate the protective film 308 to expose the cathode electrode 306, and the cathode electrodes 306 of the respective light emitting elements 300 are connected to each other by the common electrode 320 provided to cover the inner walls of the holes 322 and the protective films 308. More specifically, the protective film 308 is preferably a transparent single-layer film or multi-layer film that is formed of an inorganic material having low hygroscopicity. For example, the protective film 308 preferably includes at least one selected from the group consisting of a silicon oxide (SiO₂) (refractive index of 1.5 or less), a silicon nitride (SiN) (refractive index of 2 or less), a silicon oxynitride (SiON) (refractive index of 1.7 or less), a titanium oxide (TiO₂) (refractive index of 2.5 or less), and an aluminum oxide (Al₂O₃) (refractive index of 1.6 or less).

### (Side Wall 310)

The side wall 310 is provided to cover a side surface of a stack including the anode electrode 302, the light emitting layer 304, the cathode electrode 306, and the protective film 308. Furthermore, the side wall 310 is formed of a transparent material that has a refractive index different from that of a material forming the protective film (first protective film) 350. Furthermore, as illustrated in FIG. 13, the side wall 310 is preferably formed to have a lens-shaped cross-section protruding outside the stack. In the present embodiment, light is refracted at the interface between the side wall 310 and the protective film 350, and the side wall 310 is made to function as a lens so that the light emitted from the light emitting layer 304 can be guided in a desired direction.

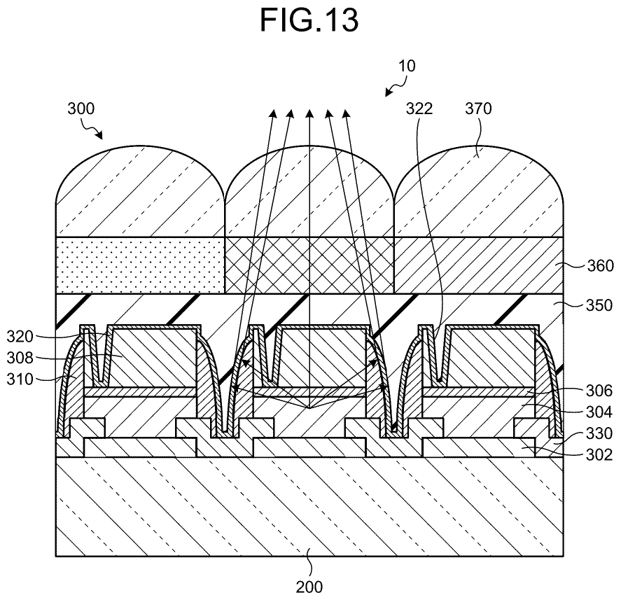

In the present embodiment, the side wall 310 is provided to extend from a position above an upper surface of the cathode electrode 306 to a position of the lower surface of the light emitting layer 304, downward in a stacking direction of the stack Furthermore, in the present embodiment, as shown in the cross-sectional view of FIG. 14, the side wall 310 is preferably provided to extend from the position of an upper surface of the protective film 308 to a position below the position of an upper surface of the anode electrode 302, downward in the stacking direction of the stack.

In addition, the side wall 310 is preferably formed of a transparent material having a refractive index higher than that of the material forming the protective film 350 which is described later, a refractive index equal to or lower than that of the material forming the protective film 308, and a refractive index of 2.5 or less Furthermore, the side wall 310 is preferably a single-layer film or multi-layer film that is formed of an inorganic material having low hygroscopicity. For example, the side wall 310 preferably includes at least one selected from the group consisting of a silicon oxide (SiO₂) (refractive index of 1.5 or less), a silicon nitride (SiN) (refractive index of 2 or less), a silicon oxynitride (SiON) (refractive index of 1.7 or less), a titanium oxide (TiO₂) (refractive index of 2.5 or less), and an aluminum oxide (Al₂O₃) (refractive index of 1.6 or less).

Furthermore, in the present embodiment, the side wall 310 may be provided to be separated from or connected to the side wall 310 of an adjacent light emitting element 300.

In the present embodiment, the side wall 310 configured as described above is provided, the interface between the side wall 310 and the protective film 350 functions as the lens due to a difference in refractive index, and therefore, light emitted from a light emitting layer 304 is allowed to be guided to a color filter 360 and a lens 370 that are positioned immediately above the light emitting layer 304. Accordingly, in the present embodiment, it is possible to prevent part of light emitted from the light emitting layer 304 from passing through not the color filter 360 positioned immediately above the light emitting layer 304 but the adjacent color filter 360 and from being condensed to the lens 370 positioned immediately above the color filter. Therefore, according to the present embodiment, light emitted from the light emitting layer 304 is allowed to be condensed by the desired lens 370, thus, improving the light extraction efficiency of the light emitting device 10, further suppressing the occurrence of a problem such as color mixing.

### (Common Electrode 320)

The common electrode 320 is an electrode electrically connected to the cathode electrode 306, and mutual connection of the common electrodes 320 of the light emitting elements 300 adjacent to each other makes it possible to function as an electrode common to the plurality of light emitting elements 300. Such a structure of the common electrode 320 makes it possible to apply a uniform voltage to the cathode electrodes 306 of the light emitting elements 300, suppressing variations in emission intensity (uneven light emission) of the light emitting elements 300. Specifically, the common electrode 320 is provided to cover the protective film 308 and the side wall 310, and further, the common electrode 320 is provided to cover the inner wall of the hole 322 penetrating the protective film 308 to expose the cathode electrode 306. In addition, the common electrode 320 is preferably formed of a transparent conductive material that has a refractive index higher than that of the material forming the protective film 350, and has a refractive index equivalent to that of the material forming the side wall 310. Note that examples of materials for forming the common electrode 320 are similar to those of the common electrode 320 of the first embodiment, and thus description thereof is omitted here.

### (Isolation Film 330)

The isolation film 330 is a film that is provided on the semiconductor substrate 200 to define the light emitting element 300, and specifically, is provided to surround the anode electrode 302. For example, the isolation film 330 can be formed of an organic or inorganic material. Specifically, examples of the organic material include a polyimide resin and an acrylic resin. Examples of the inorganic material include a silicon oxide (SiO₂), a silicon nitride (SiN), a silicon oxynitride (SiON), a titanium oxide (TiO₂), and an aluminum oxide (Al₂O₃).

Note that the light emitting element 300 according to the present embodiment is not limited to the cross-sectional structure as illustrated in FIG. 13, and for example, other elements may be added.

### <3.2 Modifications>

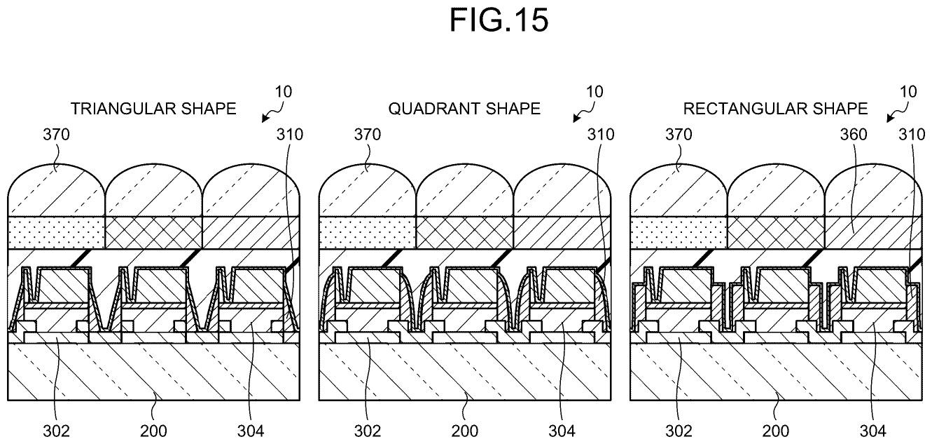

Furthermore, in the present embodiment, the structure of the light emitting device 10 can be further changed. Therefore, modifications of the present embodiment will be described with reference to FIGS. 14 to 16. FIGS. 14 to 16 are each an explanatory diagram illustrating the light emitting device 10 according to a modification of the present embodiment.

First, as illustrated in FIG. 14, in the present modification, a gap 354 may be formed between the light emitting elements 300 adjacent to each other. In this configuration, a blocking film 352 is provided on each protective film 308. Specifically, the blocking film 352 is preferably a transparent single-layer film or multi-layer film that is formed of an inorganic material having low hygroscopicity. For example, the blocking film 352 preferably includes at least one selected from the group consisting of a silicon oxide (SiO₂) (refractive index of 1.5 or less), a silicon nitride (SiN) (refractive index of 2 or less), a silicon oxynitride (SiON) (refractive index of 1.7 or less), a titanium oxide (TiO₂) (refractive index of 2.5 or less), and an aluminum oxide (Al₂O₃) (refractive index of 1.6 or less).

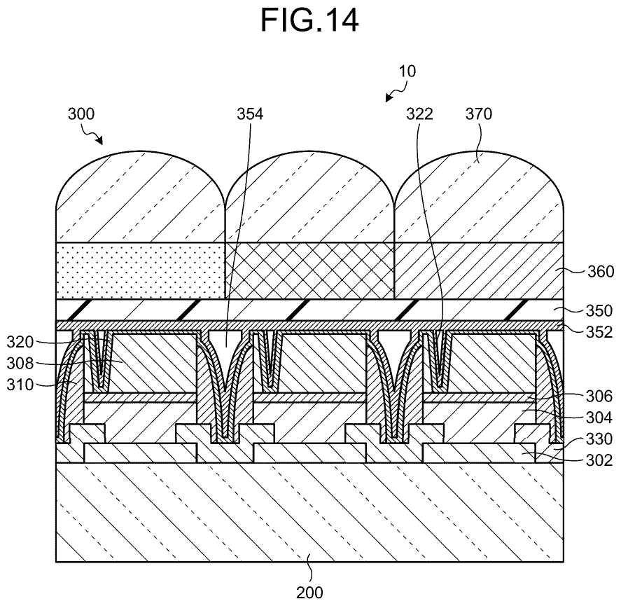

Furthermore, in the present modification, as illustrated in FIG. 15, the side wall 310 can have a cross-section of substantially right triangular shape, substantially quadrant shape, or rectangular shape, and may have a cross-section of substantially trapezoidal shape although not illustrated.

Furthermore, in the present modification, the side wall 310 may protrude to the bottom of a color filter 360 adjacent to the color filter 360 positioned immediately above the light emitting layer 304 covered by the side wall 310. In other words, when each isolation film 330 defines a section of a light emitting element 300, the side wall 310 may protrude to a section of an adjacent light emitting element 300.

Note that a cross-sectional structure of the light emitting element 300 according to the present embodiment is not limited to the examples illustrated in FIGS. 14 to 16, and can be appropriately deformed.

### <3.3 Planar Arrangement>

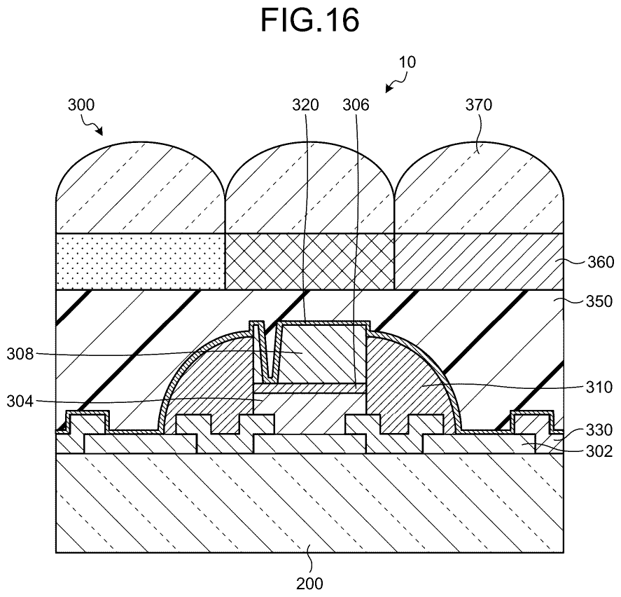

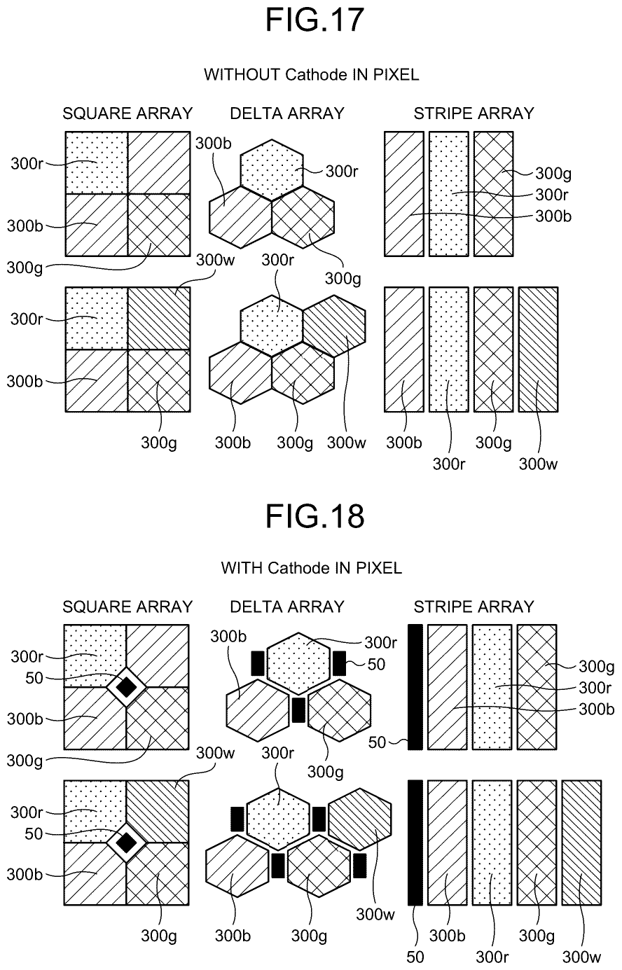

Next, an example of a planar arrangement of the light emitting elements 300 according to an embodiment of the present disclosure will be described with reference to FIGS. 17 and 18. FIGS. 17 and 18 are each an explanatory diagram illustrating an example of the planar arrangement of the light emitting elements 300 according to the present embodiment.

As described above, the light emitting elements 300 according to the present embodiment are configured to emit red light, green light, blue light, and white light. Then, as illustrated in FIG. 17, the light emitting elements 300b, 300g, 300r, and 300w that emit light of different colors are configured to be arranged in a square array (rectangular shape), a delta array (triangular shape), a stripe array, or the like, on the light emitting unit 20.

Furthermore, in the present embodiment, as illustrated in FIG. 18, the light emitting elements 300b, 300g, 300r, and 300w may be configured so that the pad 50 (or the cathode electrode) is provided between adjacent light emitting elements 300 in the light emitting unit 20

Note that the light emitting elements 300b, 300g, 300r, and 300w according to the present embodiment are not limited to the arrangements as illustrated in FIGS. 17 and 18, and another arrangement can be selected.

### 3.4 Manufacturing Method

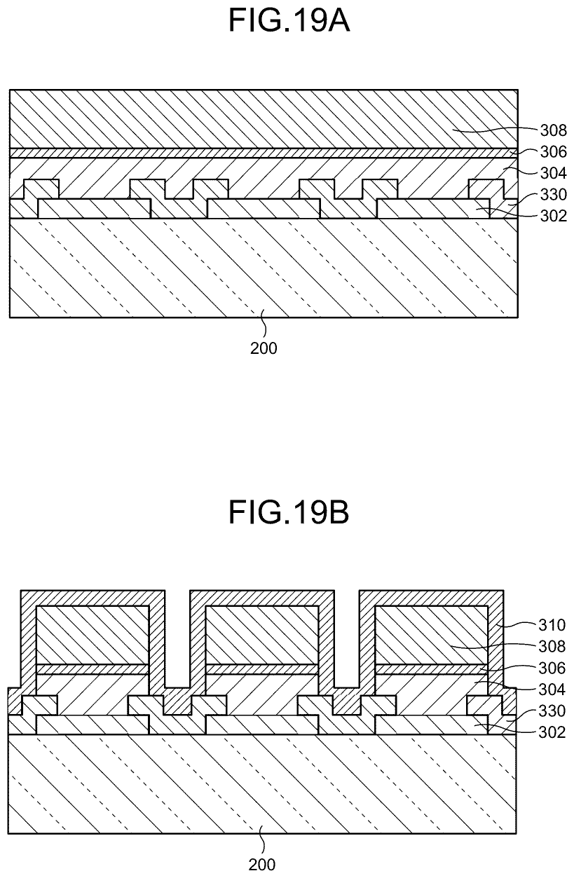

Next, a manufacturing method for the light emitting element 300 according to the present embodiment will be described with reference to FIGS. 19A to 19F. FIGS. 19A to 19F are each a schematic diagram illustrating the manufacturing method for the light emitting element 300 according to the present embodiment.

First, as illustrated in FIG. 19A, the anode electrode 302, the light emitting layer 304, the cathode electrode 306, the protective film 308, and the isolation film 330 are formed on the semiconductor substrate 200.

Next, the resist is formed on the protective film 308, and a pattern is formed on the resist by using photolithography. Then, the light emitting layer 304, the cathode electrode 306, and the protective film 308 are subjected to dry etching according to the pattern, and separated for each light emitting element 300. Furthermore, as illustrated in FIG. 19B, a film as a material of the side wall 310 is formed so as to cover a stack of the separated light emitting layer 304, cathode electrode 306, and protective film 308.

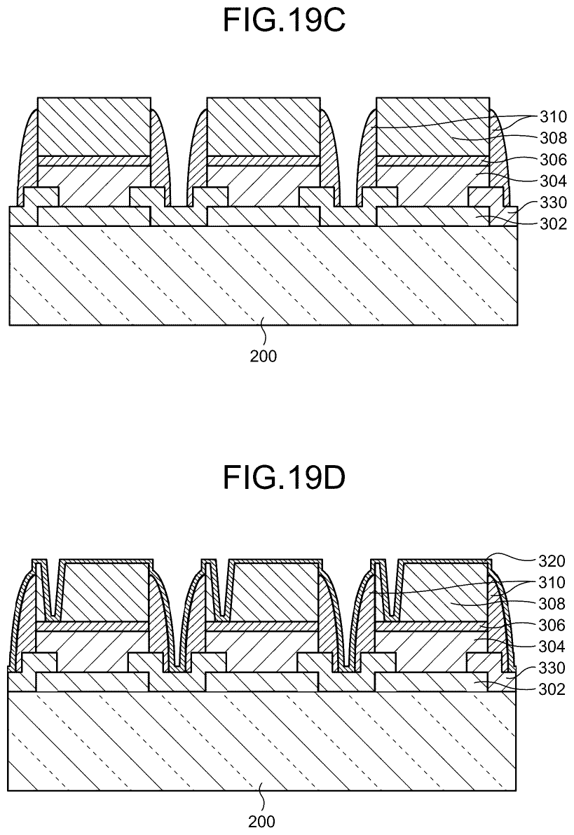

Thereafter, the entire surface of a wafer is processed by dry etching to leave the side wall 310 at the end surfaces of the protective film 308, the cathode electrode 306, the light emitting layer 304, and the anode electrode 302. At this time, the side wall 310 is preferably provided to extend from a position above the upper surface of the cathode electrode 306 to a position below the upper surface of the anode electrode 302. Furthermore, the side wall 310 preferably has a taper angle of 90 degrees or less (for details of the taper angle, see FIG. 20), and the side wall 310 may have a curved surface.

Furthermore, as illustrated in FIG. 19D, the hole 322 provided to penetrate the protective film 308 to expose the cathode electrode 306 is formed, and the common electrode 320 is formed so as to cover the protective film 308 and the side wall 310.

Then, the protective film 350 is formed so as to cover the light emitting elements 300, an upper surface of the protective film 350 is flattened, and then the color filters 360 are formed. Note that in the present embodiment, when the light emitting layer 304 described above is configured to emit blue light, green light, or red light, the color filter 360 may not be provided. Furthermore, as illustrated in FIG. 19F, the lenses 370 are formed on the color filters 360.

Note that the light emitting elements 300 according to the present embodiment and the present modification are formed by, but are not limited to, the manufacturing method as illustrated in FIGS. 19A to 19F, and the process thereof may be appropriately changed.

### 3.5 Results of Simulation

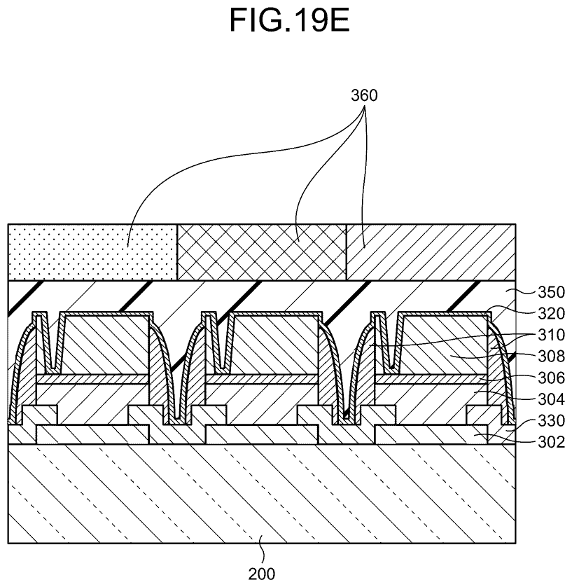

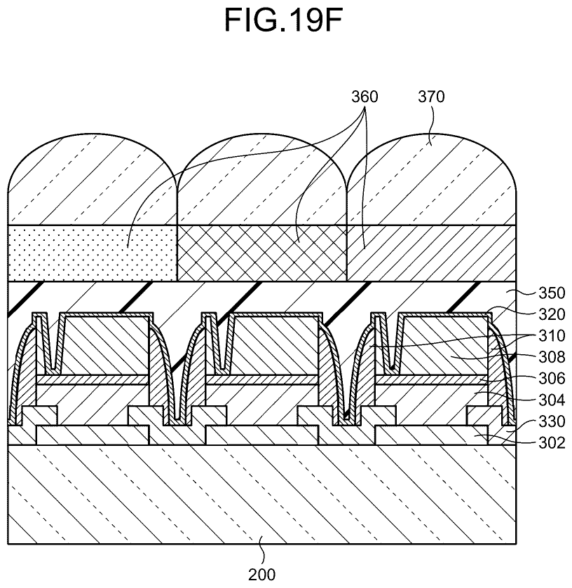

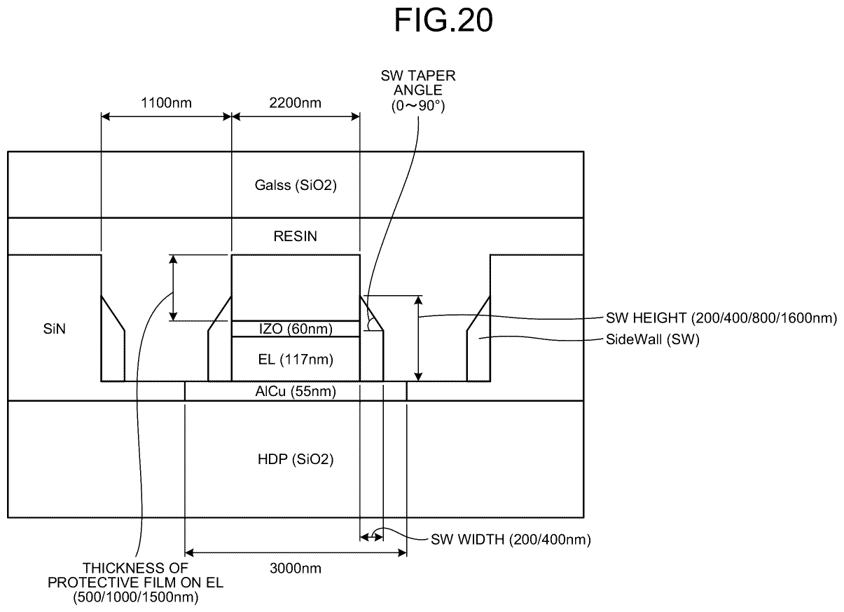

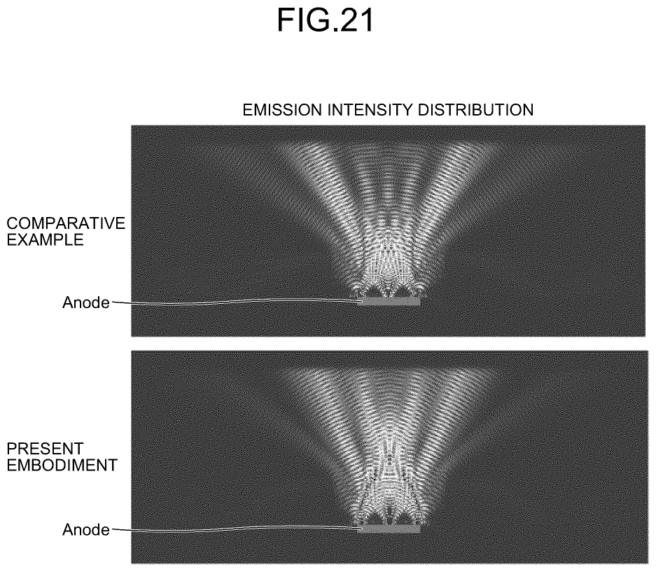

In order to verify the effects of the present embodiment, the present inventors performed an optical simulation. Therefore, results of the optical simulation for the present embodiment will be described with reference to FIGS. 20 to 24. FIG. 20 is a diagram illustrating an optical simulation model, and FIG. 21 is a diagram illustrating results of the optical simulation. Furthermore, FIG. 22 is a graph illustrating a tendency of emission intensity with respect to a height of the side wall 310, FIG. 23 is a graph illustrating a tendency of emission intensity with respect to a width of the side wall 310, and FIG. 24 is a graph illustrating a tendency of emission intensity with respect to the taper angle of the side wall 310.

In order to verify the effects according to the present embodiment, the present inventors performed the optical simulation under the conditions given by the side wall 310 of FIG. 20. Specifically, as illustrated in FIG. 20, in the optical simulation, the anode electrode 302 was made of a copper-aluminum (AlCu) alloy having a width of 3000 nm and a film thickness of 55 nm, the light emitting layer 304 was made of one organic layer having a width of 2200 nm and a film thickness of 177 nm (i.e., the light emitting layer 304 emits white light), and the cathode electrode 306 was made of indium zinc oxide (IZO) having a width of 2200 nm and a film thickness of 60 nm. For the protective film 308, three conditions of film thicknesses of 500 nm, 1000 nm, and 1500 nm were set. Furthermore, the side wall (SW) 310 was set to have a width of 200 nm or 400 nm, and heights of 200 nm, 400 nm, 800 nm, and 1600 nm, and further, the side wall 310 was set to have a taper angle between 0 degree and 90 degrees. Specific positions of the height of the side wall 310, the width of the side wall 310, and the taper angle of the side wall 310 are as illustrated in FIG. 20.

Then, in the optical simulation, the light emitting elements 300 with and without the side wall 310 were compared for differences in light travel direction, and the heights of the side wall 310, the widths of the side wall 310, and the taper angles of the side wall 310 were compared for changes in emission intensity of the light emitting element 300.

First, as illustrated in FIG. 21, as compared with a comparison example having no side wall 310, the present embodiment having the side wall 310 showed that light traveling obliquely from the light emitting layer 304 of the light emitting element 300 changed to travel immediately upward. Therefore, according to the present embodiment, the light from the light emitting layer 304 travels immediately upward due to the side wall 310, and therefore, the emission intensity of the light emitting element 300 can be improved.

Next, as illustrated in FIG. 22, it was found that the emission intensity of the light emitting element 300 is improved as the height of the side wall 310 is increased. In addition, according to the optical simulation, it was found that the emission intensity of the light emitting element 300 is improved as the film thickness of the protective film 308 increases (see FIG. 20).

Next, as illustrated in FIG. 23, it was found that the emission intensity of the light emitting element 300 is most improved when the width of the side wall 310 is in the vicinity of 200 nm.

Furthermore, as illustrated in FIG. 24, it was found that the emission intensity of the light emitting element 300 is most improved when the taper angle of the side wall 310 is in the vicinity of 60 degrees.

In the present embodiment, the interface between the side wall 310 and the protective film 350 functions as the lens due to a difference in refractive index, and therefore, light emitted from a light emitting layer 304 is allowed to be guided to a color filter 360 and a lens 370 that are positioned immediately above the light emitting layer 304. Accordingly, in the present embodiment, it is possible to prevent part of light emitted from the light emitting layer 304 from passing through not the color filter 360 positioned immediately above the light emitting layer 304 but the adjacent color filter 360 and from being condensed to the lens 370 positioned immediately above the color filter. Therefore, according to the present embodiment, light emitted from the light emitting layer 304 is allowed to be condensed by the desired lens 370, thus, improving the light extraction efficiency of the light emitting device 10, further suppressing the occurrence of a problem such as color mixing.

### 4. Conclusion

As described above, according to the embodiments of the present disclosure, the interface between the side wall 310 and the protective film 350 functions as the lens due to a difference in refractive index, and therefore, light emitted from a light emitting layer 304 is allowed to be guided to a color filter 360 and a lens 370 that are positioned immediately above the light emitting layer 304. Accordingly, in the present embodiment, it is possible to prevent part of light emitted from the light emitting layer 304 from passing through not the color filter 360 positioned immediately above the light emitting layer 304 but the adjacent color filter 360 and from being condensed to the lens 370 positioned immediately above the color filter. Therefore, according to the present embodiment, light emitted from the light emitting layer 304 is allowed to be condensed by the desired lens 370, thus, improving the light extraction efficiency of the light emitting device 10, further suppressing the occurrence of a problem such as color mixing. Note that the first embodiment and the second embodiment of the present disclosure described above may be implemented by combining part or all of the embodiments.

Furthermore, in the embodiments of the present disclosure described above, the semiconductor substrates 100 and 200 are not necessarily a silicon substrate, and may be another substrate (e.g., a silicon on insulator (SOI) substrate, a SiGe substrate, or the like).

Note that in the present embodiment, examples of the method of forming the layers and the films described above include a physical vapor deposition (PVD) method and a chemical vapor deposition (CVD) method. Examples of the PVD method include a vacuum vapor deposition method using resistance heating or high-frequency heating, an electron beam (EB) vapor deposition method, various sputtering methods (magnetron sputtering method, radio frequency (RF)-direct current (DC) coupled mode bias sputtering method, electron cyclotron resonance (ECR) sputtering method, facing target sputtering method, high-frequency sputtering method, and the like), an ion plating method, a laser ablation method, a molecular beam epitaxy (MBE) method, a laser transfer method, and the like. Examples of the CVD method include a plasma CVD method, a thermal CVD method, an MOCVD method, and a photo CVD method. Furthermore, examples of other methods include an electrolytic plating method, an electroless plating method, and a spin coating method; a dipping method; a casting method; a micro-contact printing; a drop casting method; various printing methods, such as a screen printing method, an inkjet printing method, an offset printing method, a gravure printing method, and a flexographic printing method; a stamping method; a spray method; and various coating methods, such as an air doctor coating method, a blade coater method, a rod coater method, a knife coater method, a squeeze coating method, a reverse roll coater method, a transfer roll coater method, a gravure coating method, a kiss coating method, a cast coating method, a spray coating method, a slit orifice coater method, and a calendar coating method. Furthermore, examples of a patterning method for each layer include chemical etching, such as shadow masking, laser transfer, and photolithography, and physical etching using ultraviolet rays, laser, or the like. In addition, examples of the planarization technique include a chemical mechanical polishing (CMP) method, a laser planarization method, and a reflow method. In other words, the light emitting device 10 according to the present embodiment can be readily and inexpensively manufactured by using an existing semiconductor device manufacturing process.

### 5. Application Examples

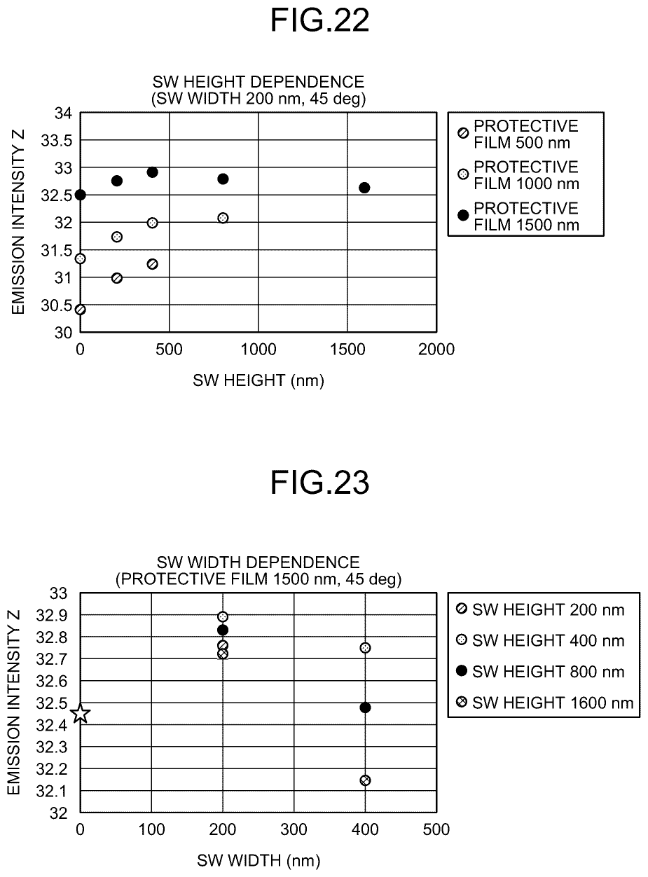

Next, an application example of the light emitting device 10 according to an embodiment of the present disclosure will be described with reference to FIGS. 25 to 28. FIGS. 25 to 28 are each an appearance view illustrating an example of an electronic device to which the light emitting device 10 according to an embodiment of the present disclosure is applicable.

For example, the light emitting device 10 according to the present embodiment is applicable to a display unit included in an electronic device such as a smartphone. Specifically, as illustrated in FIG. 25, a smartphone 600 includes a display unit 602 that displays various information, an operation unit that includes a button and the like receiving an operation input by the user, and the like. The display unit 602 can be the light emitting device 10 according to the present embodiment.

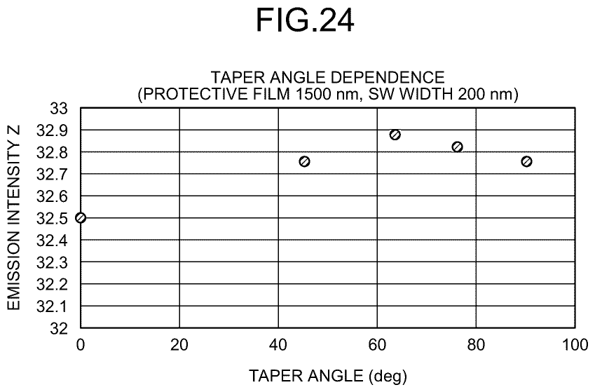

Furthermore, for example, the light emitting device 10 according to the present embodiment is applicable to a display unit of an electronic device such as a digital camera. Specifically, as shown in the appearance view of a digital camera 700 illustrated in FIG. 26 as viewed from a rear side (on the side of a camera person), the digital camera 700 includes a main unit (camera body) 702, a monitor unit 704 that displays various information, and an electronic view finder (EVF) 706 that displays a through-the-lens image observed by the user upon capturing an image. Here, the monitor unit 704 and the EVF 706 can be the light emitting device 10 according to the present embodiment.

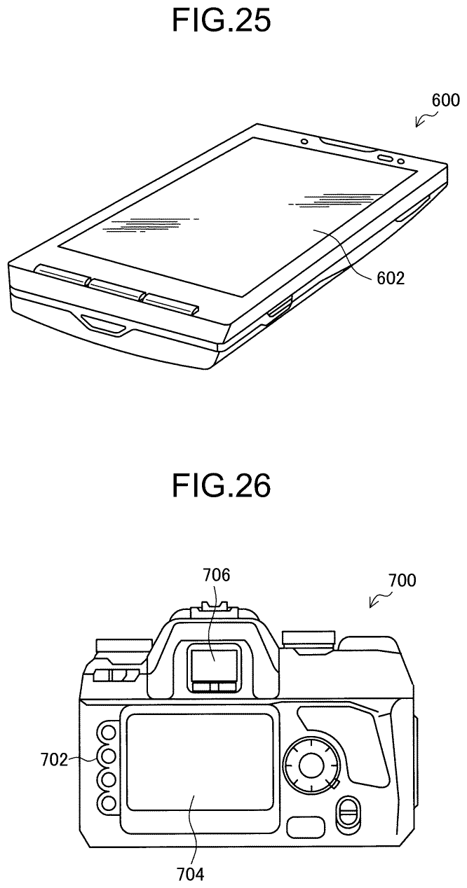

Furthermore, for example, the light emitting device 10 according to the present embodiment is applicable to a display unit of an electronic device such as a head mounted display (HMD). Specifically, as illustrated in FIG. 27, the HMD 800 includes a spectacle type display unit 802 that displays various information, and ear hook portions 804 that are hooked to the user's ears when worn. Here, the display unit 802 can be the light emitting device 10 according to the present embodiment.

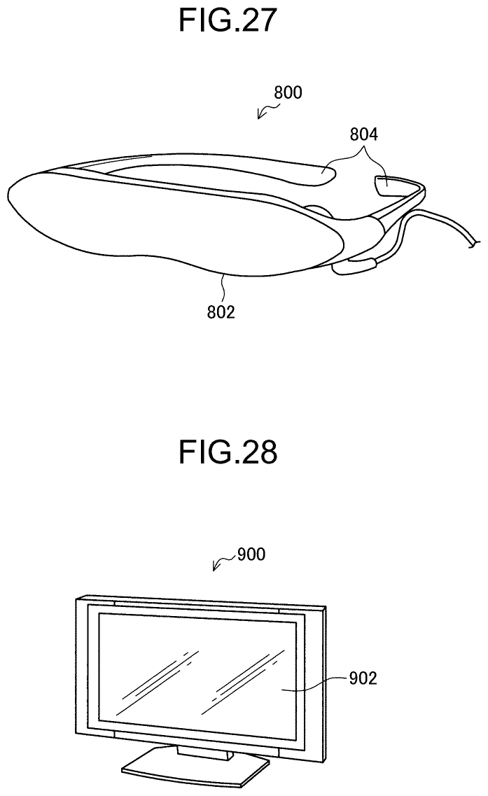

Furthermore, for example, the light emitting device 10 according to the present embodiment is applicable to a display unit of an electronic device such as a television device. Specifically, as illustrated in FIG. 28, a television device 900 includes a display unit 902 that is covered with filter glass or the like. Here, the display unit 902 can be the light emitting device 10 according to the present embodiment.

Note that the electronic device to which the light emitting device 10 according to the present embodiment is applicable is not limited to the above examples. The light emitting device 10 according to the present embodiment is applicable to the display units of electronic devices in any field that perform display on the basis of image signals input from the outside or image signals generated inside. Examples of the electronic device configured as described above include a television device, an electronic book, a personal digital assistant (PDA), a laptop personal computer, a video camera, a smartwatch, a game device, or the like.

Furthermore, the light emitting device 10 according to the present embodiment is also applicable to a lighting device, an advertisement display device, and the like.

### 6. Supplementary Notes

Preferred embodiments of the present disclosure have been described above in detail with reference to the accompanying drawings, but the technical scope of the present disclosure is not limited to these examples. A person skilled in the art may obviously find various alternations or modifications within the technical concept described in claims, and it should be understood that the alternations and modifications will naturally come under the technical scope of the present disclosure.

Furthermore, the effects descried herein are merely illustrative or exemplified effects, and are not limitative. In other words, with or in place of the above effects, the technology according to the present disclosure can provide other effects that are apparent to those skilled in the art from the description herein.

Note that the present technology can also have the following configurations.

(1) A light emitting device comprising
a plurality of light emitting elements that is arranged in a matrix on a semiconductor substrate, wherein
each of the light emitting elements provided to be covered with a first protective film includes:
a stack that includes a first electrode, a light emitting layer provided on the first electrode, a second electrode provided on the light emitting layer, and a second protective film provided on the second electrode; and
a side wall that is formed of a material having a refractive index different from that of a material forming the first protective film and covering at least part of a side surface of the stack, and
the side wall extends from a position above an upper surface of the second electrode to a position below an upper surface of the light emitting layer, downward in a stacking direction.

(2) The light emitting device according to (1), wherein the second electrode, the first and second protective films, and the side wall are formed of a transparent material.

(3) The light emitting device according to (1) or (2), wherein the side wall extends downward in the stacking direction, to a position of a lower surface of the light emitting layer.

(4) The light emitting device according to (1), wherein the side wall extends downward in the stacking direction, to a position below an upper surface of the first electrode.

(5) The light emitting device according to any one of (1) to (4), wherein the side wall extends upward in the stacking direction, to a position above an upper surface of the second protective film.

(6) The light emitting device according to any one of (1) to (5), wherein the side wall is formed of a material having a refractive index higher than that of a material forming the first protective film.

(7) The light emitting device according to (6), wherein the side wall is formed of a material having a refractive index equal to or lower than that of a material forming the second protective film.

(8) The light emitting device according to (7), wherein the side wall is formed of a material having a refractive index of 2.5 or less.

(9) The light emitting device according to any one of (1) to (8), wherein the side wall has any one of a substantially semicircular shape, a substantially trapezoidal shape, a substantially right triangular shape, a substantially quadrant shape, and a rectangular shape, in a cross-section of the light emitting element taken in the stacking direction.

(10) The light emitting device according to any one of (1) to (9), wherein the side wall of one of the light emitting elements is provided to be separated from the side wall of another one of the adjacent light emitting elements.

(11) The light emitting device according to any one of (1) to (9), wherein the side wall of one of the light emitting elements is provided to be connected to the side wall of another one of the adjacent light emitting elements.

(12) The light emitting device according to any one of (1) to (11), wherein the second protective film has a substantially semicircular cross-section with an upper arc, in a cross-section of the light emitting element taken in the stacking direction.

(13) The light emitting device according to any one of (1) to (12), wherein
the second protective film has a hole that penetrates the second protective film to expose the second electrode, and
the second electrode is electrically connected to a common electrode that covers at least part of an upper surface of the second protective film and part of an inner wall of the hole.

(14) The light emitting device according to any one of (1) to (13), wherein the second electrode has a substantially recessed shape in a cross section of the light emitting element taken in the stacking direction.

(15) The light emitting device according to any one of (1) to (14), wherein the first protective film is embedded between the light emitting elements adjacent to each other.

(16) The light emitting device according to any one of (1) to (15), further comprising a plurality of lenses that is provided above the first protective film to correspond to the respective light emitting elements.

(17) The light emitting device according to (16), further comprising a plurality of color filters that is provided below the respective lenses to correspond to the respective light emitting elements.

(18) The light emitting device according to any one of (1) to (17), wherein the light emitting layer emits at least one of white light, red light, green light, and blue light.

(19) The light emitting device according to any one of (1) to (17), wherein
the plurality of light emitting elements emits red light, green light, and blue light, and
the plurality of light emitting elements emitting light of different colors is arranged on the semiconductor substrate, in a rectangular shape, a triangular shape, or a stripe shape.

(20) An electronic device comprising one or a plurality of light emitting devices, wherein
each of the light emitting devices includes
a plurality of light emitting elements that is arranged in a matrix on a semiconductor substrate,
each of the light emitting elements provided to be covered with a first protective film includes:

a stack that includes a first electrode, a light emitting layer provided on the first electrode, a second electrode provided on the light emitting layer, and a second protective film provided on the second electrode; and
a side wall that is formed of a material having a refractive index different from that of a material forming the first protective film and covering at least part of a side surface of the stack, and
the side wall extends from a position above an upper surface of the second electrode to a position below an upper surface of the light emitting layer, downward in a stacking direction.

### REFERENCE SIGNS LIST

10 LIGHT EMITTING DEVICE
20 LIGHT EMITTING UNIT
30 PERIPHERAL CIRCUIT UNIT
33 SCANNING CIRCUIT
34 LIGHT EMISSION CONTROLLING TRANSISTOR CONTROL CIRCUIT
35 IMAGE SIGNAL OUTPUT CIRCUIT
36 FIRST CURRENT SUPPLY UNIT
37 SECOND CURRENT SUPPLY UNIT
40 DRIVE CIRCUIT UNIT
50 PAD
100, 200 SEMICONDUCTOR SUBSTRATE
300, 300b, 300g, 300r, 300w LIGHT EMITTING ELEMENT
302 ANODE ELECTRODE
304 LIGHT EMITTING LAYER
306 CATHODE ELECTRODE
308, 308a, 308b, 350 PROTECTIVE FILM
310 SIDE WALL
320 COMMON ELECTRODE
322 HOLE
330 ISOLATION FILM
352 BLOCKING FILM
354 GAP
360 COLOR FILTER
370 LENS
380 OPPOSED GLASS
400, 402, 404 RESIST
600 SMARTPHONE
602, 802, 902 DISPLAY UNIT
700 DIGITAL CAMERA
702 MAIN UNIT
704 MONITOR UNIT
706 EVF
800 HMD
804 EAR HOOK PORTION
900 TELEVISION DEVICE

1. A light emitting device comprising
a plurality of light emitting elements that is arranged in a matrix on a semiconductor substrate, wherein
each of the light emitting elements provided to be covered with a first protective film includes:
a stack that includes a first electrode, a light emitting layer provided on the first electrode, a second electrode provided on the light emitting layer, and a second protective film provided on the second electrode; and
a side wall that is formed of a material having a refractive index different from that of a material forming the first protective film and covering at least part of a side surface of the stack, and
the side wall extends from a position above an upper surface of the second electrode to a position below an upper surface of the light emitting layer, downward in a stacking direction.

2. The light emitting device according to claim 1, wherein the second electrode, the first and second protective films, and the side wall are formed of a transparent material.

3. The light emitting device according to claim 1, wherein the side wall extends downward in the stacking direction, to a position of a lower surface of the light emitting layer.

4. The light emitting device according to claim 1, wherein the side wall extends downward in the stacking direction, to a position below an upper surface of the first electrode.

5. The light emitting device according to claim 1, wherein the side wall extends upward in the stacking direction, to a position above an upper surface of the second protective film.

6. The light emitting device according to claim 1, wherein the side wall is formed of a material having a refractive index higher than that of a material forming the first protective film.

7. The light emitting device according to claim 6, wherein the side wall is formed of a material having a refractive index equal to or lower than that of a material forming the second protective film.

8. The light emitting device according to claim 7, wherein the side wall is formed of a material having a refractive index of 2.5 or less.

9. The light emitting device according to claim 1, wherein the side wall has any one of a substantially semicircular shape, a substantially trapezoidal shape, a substantially right triangular shape, a substantially quadrant shape, and a rectangular shape, in a cross-section of the light emitting element taken in the stacking direction.

10. The light emitting device according to claim 1, wherein the side wall of one of the light emitting elements is provided to be separated from the side wall of another one of the adjacent light emitting elements.

11. The light emitting device according to claim 1, wherein the side wall of one of the light emitting elements is provided to be connected to the side wall of another one of the adjacent light emitting elements.

12. The light emitting device according to claim 1, wherein the second protective film has a substantially semicircular cross-section with an upper arc, in a cross-section of the light emitting element taken in the stacking direction.

13. The light emitting device according to claim 1, wherein
the second protective film has a hole that penetrates the second protective film to expose the second electrode, and
the second electrode is electrically connected to a common electrode that covers at least part of an upper surface of the second protective film and part of an inner wall of the hole.

14. The light emitting device according to claim 1, wherein the second electrode has a substantially recessed shape in a cross section of the light emitting element taken in the stacking direction.

15. The light emitting device according to claim 1, wherein the first protective film is embedded between the light emitting elements adjacent to each other.

16. The light emitting device according to claim 1, further comprising a plurality of lenses that is provided above the first protective film to correspond to the respective light emitting elements.

17. The light emitting device according to claim 16, further comprising a plurality of color filters that is provided below the respective lenses to correspond to the respective light emitting elements.

18. The light emitting device according to claim 1, wherein the light emitting layer emits at least one of white light, red light, green light, and blue light.

19. The light emitting device according to claim 1, wherein
the plurality of light emitting elements emits red light, green light, and blue light, and
the plurality of light emitting elements emitting light of different colors is arranged on the semiconductor substrate, in a rectangular shape, a triangular shape, or a stripe shape.

20. An electronic device comprising one or a plurality of light emitting devices, wherein
each of the light emitting devices includes
a plurality of light emitting elements that is arranged in a matrix on a semiconductor substrate,
each of the light emitting elements provided to be covered with a first protective film includes:
a stack that includes a first electrode, a light emitting layer provided on the first electrode, a second electrode provided on the light emitting layer, and a second protective film provided on the second electrode; and
a side wall that is formed of a material having a refractive index different from that of a material forming the first protective film and covering at least part of a side surface of the stack, and
the side wall extends from a position above an upper surface of the second electrode to a position below an upper surface of the light emitting layer, downward in a stacking direction.
